(19) United States
(12) Patent Application Publication
(10) Pub. No.: US 2019/0191588 A1
(43) Pub. Date: Jun. 20, 2019

(54) Electronics Cabinet With Integrated Cooling System, Reconfigurable Mounting System, or Both

(71) Applicant: Dover Europe Sàrl, Vernier (CH)

(72) Inventors: Nicky Bond, Lowdham (GB); Vincent Audouard, Toulaud (FR)

(21) Appl. No.: 16/286,368

(22) Filed: Feb. 26, 2019

Related U.S. Application Data
(60) Provisional application No. 62/640,510, filed on Mar. 8, 2018.

(51) Int. Cl. H05K 7/20

(52) U.S. Cl. CPC H05K 7/206; H02B 1/30; H05K 7/207; H05K 7/20572

(57) ABSTRACT

Systems and apparatus for housing electronics for industrial systems, such as industrial product marking systems, include a cabinet including: a frame defining an exterior channel; a side panel that attaches to the frame, and a handle located in the side panel and defining a vent hole within the handle, the vent hole being aligned with the channel, thereby allowing air to cool equipment when present within an interior portion of the frame. The systems and apparatus further include a cabinet including: a frame; and a panel configured to attach to a side of the frame separate from its two walls; wherein each of the two walls on opposite sides of the frame defines a shape that receives a structure to support the cabinet and receives fasteners on both sides of the wall to mount equipment on both an interior portion of the frame and an exterior portion of the frame.

### CROSS-REFERENCE TO RELATED APPLICATION

This application claims the benefit of priority from U.S. Provisional Application No. 62/640,510 entitled “Electronics Cabinet With Integrated Cooling System, Reconfigurable Mounting System, or Both” and filed on Mar. 8, 2018, which is incorporated herein by reference in its entirety.

### BACKGROUND

This specification relates to cabinets designed to house electronics for industrial systems, such as industrial product marking systems.

Industrial product marking systems, such as ink jet printing systems, are widely employed in product manufacturing, packaging and distribution facilities. Such product marking systems are used to add product codes, such as barcodes, serials numbers, sell-by dates, etc., to products, their packaging, or collections of products (e.g., a pallet with multiple products on it). Moreover, such product marking systems are often built into cabinets that facilitate cooling and relocating of the product marking systems within a particular facility, and in some cases the cabinets are also designed to facilitate reconfiguration of the electronics equipment that is housed in the cabinet. In addition, when the electronics cabinet is to be used in a wash-down environment, such as can be found in food packaging facilities, the cabinet should be designed to protect the housed electronics from contaminants, e.g., dust and liquids, during the wash-down process.

### SUMMARY

This specification describes technologies relating to cabinets designed to house electronics for industrial systems, such as industrial product marking systems.

In general, one or more aspects of the subject matter described in this specification can be embodied in one or more cabinets that include: a frame configured to receive equipment within an interior portion of the frame, wherein the frame defines at least part of a channel on an exterior portion of the frame; at least one side panel that attaches to the frame; and a handle located in the at least one side panel, wherein the handle defines a vent hole within the handle, and the vent hole is aligned with the channel, thereby allowing air to flow through the vent hole into the channel to cool the equipment when present within the interior portion of the frame. These and other embodiments can optionally include one or more of the following features.

The handle can be a recessed handle that extends through the at least one side panel, and the at least one vent hole can be located in an upper, interior portion of the recessed handle. The recessed handle can attach to the frame and can include a retaining edge that holds the at least one side panel to the frame, thereby forming the channel between the exterior portion of the frame and an interior portion of the at least one side panel. The recessed handle can include an injection molded part including a molded quick release clip to hold the recessed handle to the at least one side panel. Further, the cabinet can include screws or bolts that attach the recessed handle to the frame, and pins that attach the at least one side panel to the frame by mating with keyhole slots in the frame.

The cabinet can include: a front panel; quick release hinges configured and arranged to attach the front panel to the cabinet, such that the front panel is fully removable from an open position using the quick release hinges when the front panel is in the open position; and a gasket configured and arranged to form a seal between front panel and the frame, when the front panel is in a closed position, to prevent ingress of contaminants into the interior portion of the frame when the front panel is in the closed position. The gasket can include a pitched portion to direct a flow of liquid responsive to gravity. The frame can include one or more exterior edges, adjacent to the gasket, that are angled with respect to a plane associated with the gasket, such that liquid is directed away from the gasket by the one or more angled exterior edges, responsive to gravity, when the cabinet is positioned with the plane perpendicular to the direction of the gravity.

The cabinet can include an air filter located in a top portion of the cabinet and separating the channel on the exterior portion of the frame from the interior portion of the frame, wherein the recessed handle is located in a bottom portion of the cabinet, the frame including a material that defines a portion of the channel between the recessed handle and the air filter, and the material includes a heat sink. Further, the cabinet can include a modular fan assembly located in the bottom portion of the cabinet.

One or more aspects of the subject matter described in this specification can also be embodied in one or more cabinets that include: a frame including two walls on opposite sides of the frame; and at least one panel configured to attach to at least one side of the frame separate from the two walls; wherein each of the two walls on the opposite sides of the frame defines a shape that (i) receives a structure to support the cabinet, and (ii) receives fasteners on both sides of the wall to mount equipment on both an interior portion of the frame and an exterior portion of the frame. These and other embodiments can optionally include one or more of the following features.

The shape that receives the fasteners on both sides of the wall can include multiple T-slots. The multiple T-slots can include: at least five T-slots on the wall side interior to the frame; and at least two T-slots on the wall side exterior to the frame. A distance between the at least two T-slots can be equivalent to a distance between the first and third of the at least five T-slots, which is equivalent to a distance between the second and fourth of the at least five T-slots, which is equivalent to a distance between the third and fifth of the at least five T-slots.

Each of the two walls can include extruded aluminum that forms the shape. The frame can include the two extruded aluminum walls, a molded plastic top piece, and a molded plastic bottom piece, and the cabinet can include cage nut assemblies that couple the two extruded aluminum walls with the top and bottom molded plastic pieces. The two extruded aluminum walls and the top and bottom molded plastic pieces can define tube slots configured and arranged to interchangeably receive feet structures or pillar structures. A proper subset of the cage nut assemblies can have associated connectors through which side panels are attached to the cabinet. The shape that receives the structure to support the cabinet can define holes on either end of the wall configured to interchangeably receive feet structures or pillar structures. Further, the shape can include a profile that receives a cable and grommet.

Various embodiments of the subject matter described in this specification can be implemented to realize one or more of the following advantages. An electronics cabinet (also referred to as a control box) can include an integrated cooling system with one or more handles (useable for lifting the cabinet) that include air intake holes, where the combination of the air intake holes for the cabinet's cooling system with the cabinet handles eliminates the need to place additional holes in the cabinet. This can provide further advantages in wash-down environments (e.g., using recessed handle(s) with the integrated air intake holes) by reducing the chance of contaminants entering the cabinet's cooling system. In some implementations, an exterior dressing handle for the cabinet can serve four different functions concurrently: (1) a lifting point for the cabinet, (2) a holder to fix and secure the outer side panels to the cabinet frame, (3) a vent to allow fresh air to enter the cabinet, and (4) a flow guide to direct the air over a heat sink (e.g., an interior extrusion wall) before reaching a filter at an entry point into the interior of the cabinet. Using one part to achieve all these functions can save space and component costs, as well as reduce assembly time.

The vent handle can be located at or close to the bottom of the cabinet, while the filter is located at or near the top of the cabinet, with an air channel (e.g., through the heat sink) there between, which can improve performance in wash-down environments. By locating the filter toward the top of the cabinet, a good distance away from the air inlet toward the bottom of the cabinet, any splashing of liquid that may enter through the air inlet will not travel far enough (due to gravity) to reach the filter assembly. This reduces the risk that the filter media will absorb liquids during a wash-down event, which can result in unexpected filter wear and possibly the development of mildew and bacteria in the filter.

In addition, various coupling/attachment mechanisms can be used to reduce the risk of injury during manual handling of the cabinet. A quick release mechanism can be used to replace the side panel's, which aids cooling of an internal frame wall, and reduces the number of components for the cabinet. An injection molded handle can be designed to reduce part cost and assembly cost, where the injection molded handle includes one or more molded quick release clips to hold the side panel (also referring to as the dressing), one or more holes to allow fasteners to go through to fix the handle to the cabinet frame, and one or more orifices in the top of the handle to allow air to pass through and to be guided over the outer surfaces of the heat sink.

Quick removal mechanisms for the exterior panels/dressings facilitate cleaning the system and also facilitate access to internal components for servicing the system. The cabinet system can provide the ability to meet different application environment requirements (e.g., different with regard to thermal requirements and/or sanitary requirements). Moreover, the cabinet system can be readily customized by adding the walls of a selected size just prior to shipment. Some commonality in control box panels across different size boxes allows for stocking a lower amount of panels for an array of boxes (xlarge, large, medium, small). The exterior panels/dressings can also be modified, such as by constructing the exterior panels/dressings using different materials, without changing the overall structure of the cabinet system, which allows a wide variety of different electronics cabinets to be rapidly and inexpensively created using a common cabinet design platform. Moreover, the cabinet design facilitates assembly in the field (depending on the application set up), and a cabinet in the field can be readily repaired, upgraded or replaced if damaged.

Further, various features can be employed to improve the cabinet's Ingress Protection (IP) rating. The gaskets (or seals) around the access door(s) as well as the shape of the cabinet's frame can be designed to facilitate liquid drainage from the cabinet in wash-down environments. This can help to prevent the buildup of contamination (e.g., food and liquids) so as to help prevent bacteria growth, in particular at locations with small openings/access, which can be difficult to clean. For example, the cabinet design can help prevent contamination buildup at or near where mating surfaces come together, such as at the top edge of a closed door.

Moreover, internal and external mounting structures can be provided that facilitate the mounting and remounting (or reconfiguration) of electronic components within the cabinet, as well as mounting of other items to the exterior of the cabinet and/or mounting the cabinet to other structures. The frame of the cabinet can be designed with various slots, including slots to receive bolts or screws for mounting equipment to the cabinet (and/or the cabinet to equipment) and slots to receive tubes or pillars for supporting/mounting the cabinet in a particular facility (and/or for supporting/mounting additional equipment to the cabinet). Thus, the frame design for the cabinet can provide significant versatility in actual deployment of the cabinet to house specific, different electronics equipment, without significant (or potentially any) changes in the design of the cabinet that is used across product categories.

In addition, regardless of whether or not the cabinet frame employs a reconfigurable mounting system, as described, the frame of the cabinet can employ materials and frame construction mechanisms that facilitate making changes to the overall cabinet structure (e.g., changes to dimensions, mounting system structures, cooling system structures, or a combination thereof) without having to make significant changes in the cabinet construction processes. The cabinet design can allow for the use of a common cabinet platform that can be scaled to adapt to many different machine technologies. Further, the frame construction mechanisms can assist with using different materials with different manufacturing tolerances (e.g., extruded aluminum versus injection molded plastic) to construct the frame of the cabinet.

The details of one or more embodiments of the subject matter described in this specification are set forth in the accompanying drawings and the description below. Other features, aspects, and advantages of the invention will become apparent from the description, the drawings, and the claims.

### BRIEF DESCRIPTION OF THE DRAWINGS

FIGS. 1A-1G show various perspectives of an example of a cabinet designed to house control electronics for industrial systems, such as industrial product marking systems.

FIG. 2A shows an exploded view of a cabinet in accordance with the present disclosure.

FIGS. 2B-2D show an example of a vent handle attached to a side panel of the electronics cabinet.

FIGS. 3A-3H show examples of vent handles for use with the electronics cabinet.

FIGS. 4A-4D show an example of an air intake system for the electronics cabinet.

FIGS. 5A-5H show examples of modular filter and fan cooling assemblies for electronics cabinets in accordance with the present disclosure.

FIGS. 6A-6C show examples of extruded aluminum side walls in accordance with the present disclosure.

FIGS. 7A-7H show examples of connectors used to attach top and bottom pieces to the side walls, to form a cabinet frame, and to attach side panels to the frame.

FIGS. 8A & 8B show examples of gasket and frame designs that assist with drainage from an electronics cabinet in a wash-down environment.

FIGS. 9A & 9B show an example of a quick mount/release fastener, as can be used with access door(s) of the electronics cabinet.

FIGS. 10A-10D show examples of applications that utilize a reconfigurable mounting system designed for the electronics cabinet.

FIGS. 11A-11F show additional examples of applications that utilize a reconfigurable mounting system designed for the electronics cabinet.

Like reference numbers and designations in the various drawings indicate like elements.

### DETAILED DESCRIPTION

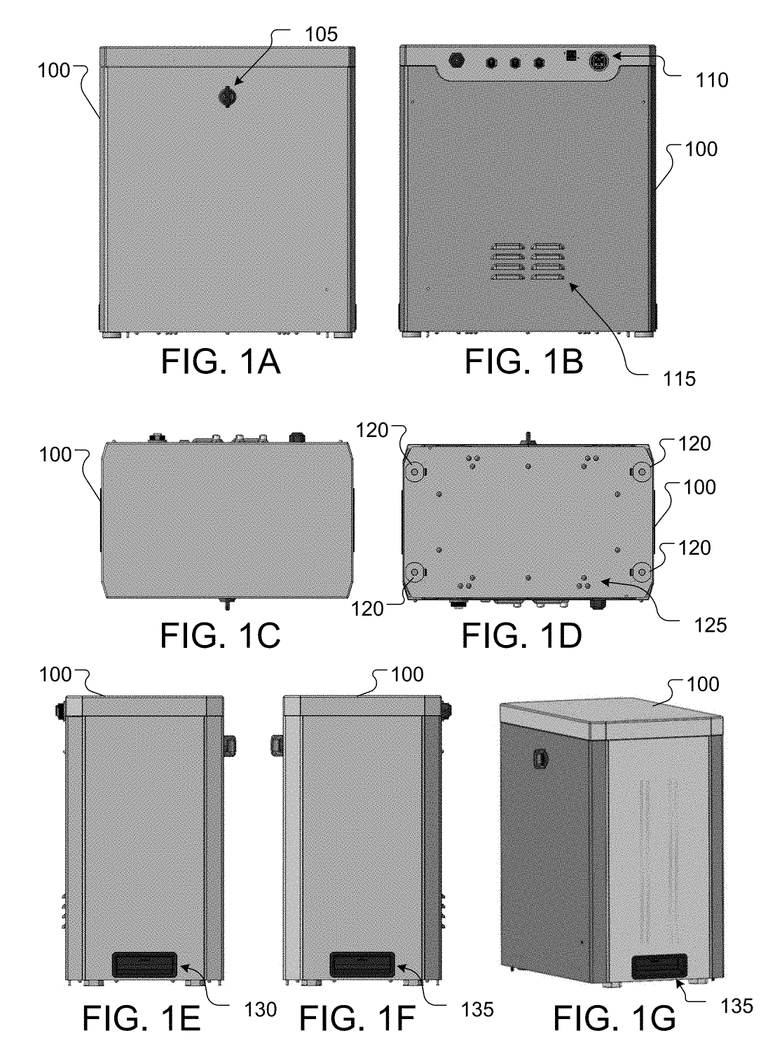

FIG. 1A shows a front view of an example of a cabinet 100 designed to house control electronics for industrial systems, such as industrial product marking systems. Examples of industrial product marking systems includes thermal transfer (TT) printer technology, drop on demand (DOD) printer technology, thermal inkjet (TIJ) printer technology, continuous ink jet (CIJ) printer technology, laser marking technology, and print & apply technology. Other electronics equipment can also be housed within the cabinet 100, for example, various control boxes for industrial equipment outside of the printing industry also require or benefit from drawing external air into the control box for cooling internal components. In general, the electronics equipment can include PCBs (Printed Circuit Boards), power supplies, batteries, electronic filters, fans, etc.

The electronics cabinet 100 can include one or more latches 105 that can be operated by a person without tools to gain access to the equipment inside the cabinet 100. The cabinet 100 can include various fasteners to attach the cabinet components together, such as described in detail below. In addition, the electronics cabinet 100 can include various input and output ports, which can vary from one implementation to another.

FIG. 1B shows a back view of the cabinet 100. In a top portion of the cabinet 100, one or more electronic input and/or output (I/O) ports 110 are included to provide electricity and/or data communications to the electronic equipment that is placed inside the cabinet 100. These I/O port(s) 110 can include a receptacle for an alternating current (AC) power cord plug, one or more coaxial cable ports, and/or one or more universal serial bus (USB) ports. In the example shown, the I/O ports 110 include and IEC connector for mains power, an M12 connector for an encoder, a print trigger & beacon port, and a USB-A, RJ45 for Ethernet. In some implementations, the set of I/O ports 110 includes a wide variety of different I/O ports that support various different types of electronics equipment that may be installed inside the cabinet 100, which allows a single cabinet 100 to be built that can be used to house a wide variety of different types of electronics equipment.

The electronics cabinet 100 includes structures that facilitate removal of heat that is generated within the cabinet 100, e.g., from the electronics operating within cabinet 100 and potentially other components (e.g., a laser). Thus, the electronics cabinet 100 includes outflow vents 115 through which heated air is expelled from the cabinet 100.

FIG. 1C shows a top view of the equipment cabinet 100, and FIG. 1D shows a bottom view of the equipment cabinet 100. In the example shown, the bottom of the cabinet 100 includes feet 120 and screws or bolts 125 used to secure a bottom cover of the cabinet 100. FIG. 1E shows a left side view of the cabinet 100, including a left side handle 130, and FIG. 1F shows a right side view of the cabinet 100, including a right side handle 135. In the example shown, the two handles 130, 135 are identical to each other and are placed at the very bottom of the cabinet 100. However, in some implementations, the two handles 130, 135 can be mirror images of each other, or entirely different from each other, and the handles 130, 135 need not be placed all the way at the bottom of the cabinet 100, provided the handles 130, 135 facilitate the cabinet 100 being lifted and positioned as needed.

As will be appreciated, the specific shapes, contours and placement of the components on the exterior of the cabinet 100, which affect the cabinet's appearance, can be readily modified for aesthetic reasons. However, other aspects of the cabinet provide functional features that improve the utility of the cabinet 100, such as the specific I/O ports 110 included in the cabinet 100. In some implementations, the electronics cabinet 100 is designed for use in environments where contaminants are present, such as dust or liquids found in a product manufacturing and/or packaging facility, and the cabinet 100 can be designed to limit the ingress of contaminants into the cabinet 100, where those contaminants can cause damage to the electronics equipment within the cabinet 100.

FIG. 1G shows a perspective view of the electronics equipment cabinet 100, including the right side handle 135. Taking advantage of the openings made in the cabinet 100 for the handles 130, 135, holes can be added to the handles 130, 135, where these holes serve as vents to allow for the air intake for a cooling system inside the cabinet 100. Combining the vent with the handle improves the cabinet by eliminating any need to place a separate vent hole opening in the cabinet to draw in air, and fewer holes in the cabinet means fewer avenues by which contaminants can attempt to get inside the cabinet.

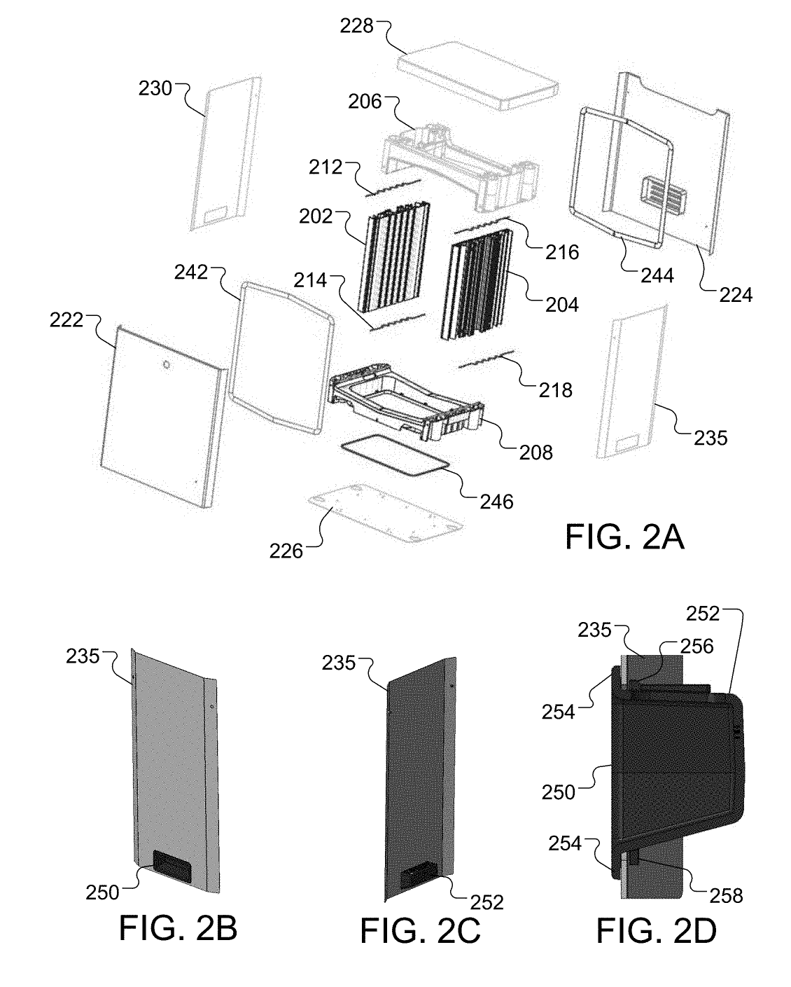

FIG. 2A shows an exploded view of a cabinet in accordance with the present disclosure. The cabinet is composed of a frame for receiving equipment within an interior portion of the frame, exterior pieces that cover the frame, and seals and gaskets that prevent contaminants, such as dust or liquids, from entering the interior portion of the frame. In some implementations, the frame is made up a left side wall 202, a right side wall 204, a top piece 206, and a bottom piece 208.

The two side walls 202, 204 can be built at least partially from metal, such as stainless steel or aluminum. In some implementations, each of the side walls 202, 204 is a piece of extruded aluminum having a specific shape, such as detailed below. Note that the use of extruded aluminum can provide advantages in terms of cost of production for the cabinet and an improved strength to weight ratio. Moreover, the design of the cabinet and the use of extrusion techniques for manufacturing the walls 202, 204, allows the height of the cabinet to be readily changed without significant changes to the manufacturing processes for the cabinet. Nonetheless, in some implementations, rather than using extruded aluminum side walls 202, 204, the side walls 202, 204 are constructed by welding and/or bolting together metal pieces of appropriate sizes and shapes (e.g., corresponding the specific shape of the extruded aluminum side wall detailed below) to form the structure of the side walls 202, 204.

The top and bottom pieces 206, 208 can be built from plastic, such as PP (Polypropylene), PBT (Polybutylene Terephthalate), PVC (Polyvinyl Chloride), ABS (Acrylonitrile Butadiene Styrene), PS (Polystyrene), PE (Polyethylene), PC (Polycarbonate), PMMA (Polymethylmethacrylate), PET (Polyethylene Terephthalate), ASA (Acrylonitrile Styrene Acrylate), and/or other suitable plastics. In some implementations, each of the pieces 206, 208 is a molded plastic part. Note that injection molding manufacturing techniques can be used to form the top and bottom pieces 206, 208 in a very cost effective manner and still provide sufficient strength without unnecessary weight for the cabinet. Moreover, as long as the locations on the pieces 206, 208 that provide points at which to fasten the pieces 206, 208 to the side walls 202, 204 (as described in detail below) remain the same, the width of the pieces 206, 208 can be readily changed to increase the width of the cabinet without needing to make any changes to the design of the side walls 202, 204.

The seals and gaskets include seals 212, 214, 216, 218, which prevent contaminants from entering the interior of the frame. The left side seals 212, 214 match a shape of the left side wall 202, and the right side seals 216, 218 match a shape of the right side wall 204. Moreover, the left and right side walls 202, 204 can be identical to each other, or mirror images of each other, and thus the seals 212, 214, 216, 218 can be identical to each other and simply placed in an appropriate orientation during construction of the cabinet. The seals 212, 216 create a barrier for contaminants that might otherwise get into the interior of the cabinet through the space between the walls 202, 204 and the top piece 206, and the seals 214, 218 create a barrier for contaminants that might otherwise get into the interior of the cabinet through the space between the walls 202, 204 and the bottom piece 208. In some implementations, the seals 212, 214, 216, 218 are constructed on the top and bottom pieces 206, 208 using the known 2-shot mold process or the known over molding process.

The exterior pieces can include a front panel 222, a back panel 224, a bottom cover 226, a top cover 228, a left side panel 230, and right side panel 235, all of which attach to the frame of the cabinet. In some implementations, the front panel 222 is secured at the top of the cabinet with a latch while the back panel 224 is attached at the top using screws or bolts. In other implementations, each of the front and back panels 222, 224 uses a latch to provide easy access to the cabinet interior from either side of the cabinet. Moreover, the seals and gaskets include a front gasket 242, a back gasket 244, and a bottom gasket 246. The front gasket 242 is compressed between the frame and the front panel 222 when the front panel 222 is attached to the frame, thereby creating a barrier for contaminants that might otherwise get into the interior of the cabinet through the front side of the frame. The back gasket 244 is compressed between the frame and the back panel 224 when the back panel 224 is attached to the frame, thereby creating a barrier for contaminants that might otherwise get into the interior of the cabinet through the back side of the frame. The bottom gasket 246 is compressed between the frame and the bottom cover 226 when the bottom cover 226 is attached to the frame, thereby creating a barrier for contaminants that might otherwise get into the interior of the cabinet through the bottom side of the frame. Further, one or more additional seals and gaskets are included for the top side of the frame, where the design of such seals and gaskets is subject to the design of the top cover 228, which can be varied. Moreover, in some implementations, one or more of the gaskets (e.g., the front gasket 242, the back gasket 244 and the bottom gasket 246) are manufactured using the known foam in place of gasket method.

The cabinet design allows for the quick customization and design of a new model industrial printer in a short amount of time since many (if not most) of the design details and manufacturing processes can be kept the same while changes in dimensions are made for the new model printer. In some cases, a set number of cabinet sizes can be adopted, e.g., small, medium, large, and extra-large versions of the cabinet. In some cases, the cabinet system can be customized by adding the walls 202, 204 and panels 222, 224, 230, 235 of a selected size just prior to shipment. Moreover, in addition to changing dimensions, the cabinet design also allows further customization of the exterior panels 222, 224, 230, 235. These exterior panels can be constructed using different materials, without changing the overall structure of the cabinet system. For example, the material used to construct the exterior panels 222, 224, 230, 235 (and potentially other exterior components, such as the top cover 228) can be selected from different material types, such as stainless steel, painted steel, aluminum, plastic, etc., which can provide cost and/or operational advantages by allowing a specific iteration of the cabinet to be tailored to a specific target application, e.g., different exterior colors based on the products being handled (food versus non-food products) and/or the locations of the different cabinets. Note that the different materials and/or colors used for the exterior portions of the cabinet can be determined in a final stage of cabinet customization.

In addition, it should be noted that, regardless of the specific dimensions and/or appearances adopted, once the top and bottom covers, and the front and back panels are in place, the seals and gaskets effectively seal off the interior of the cabinet from contaminants.

This allows the cabinet to protect the electronic equipment therein in a wash-down environment, where the cabinet is expected to be able to protect the equipment when sprayed with water and potentially cleaning chemicals, e.g., in a food packaging factory. However, the sealed off portion of the cabinet does not include the space between the walls 202, 204 and the side panels 230, 235. This can be advantageous since one or more of the side panels 230, 235 can be removed (and even left off) without affecting the Ingress Protection (IP) rating of the cabinet. In some implementations, the electronics cabinet is sealed and rated for IP66 and keeps its rating regardless of whether or not the side panels 230, 235 (also referred to as side dressings) are attached to the cabinet.

FIGS. 2B-2D show an example of a vent handle 250 attached to a side panel 235 of the cabinet. FIG. 2B shows the front side of the panel 235 (forming a part of the cabinet's exterior) with the handle 250 installed therein. FIG. 2C shows the back side of the panel 235 (forming a part of the cabinet's air intake system) with the main body 252 of the handle 250 poking through the hole in the panel 235 made for the handle 250. As shown, the handle 250 is a recessed handle that extends through the side panel 235. In various implementations, the handle 250 can be attached to the panel 235, to the frame, or to both.

FIG. 2D is a cross-sectional view of the panel 235 with the handle 250 extending through the opening in the panel 235. In the example shown, the handle 250 attaches to the frame (e.g., to the bottom piece 208, as described in further detail below) and includes a retaining edge 254 that holds the panel 235 to the frame when the handle 235 is attached to the frame. In some implementations, the retaining edge 254 is a flange that extends around the entire circumference of the handle 250, thereby providing many points of contact for holding the bottom portion of the panel 235 to the frame. Other configurations are also possible, where the retaining edge can be on only one or more sides, but not all sides, of the handle 250 (e.g., retaining clips). In any case, by providing the retaining edge, the handle 250 can be attached to the frame and also serve to hold the bottom portion of the panel 235 to the frame without any additional attachment points for the bottom portion of the panel 235, which can simplify attachment and removal of the panel 235 to the frame.

Further, in some implementations, the handle 250 does not explicitly attach to the panel 235 but rather only attaches to the frame, and it is the retaining edge 254 and the dimensions of the panel 235, the handle 250, and the frame that holds the handle 250 in place in relation to the panel 235. In other implementations, the handle 250 is attached to the panel 235. Various types of attachment mechanisms and construction materials can be used for the handle 250. In the example shown, the handle 250 is constructed of plastic (e.g., an injection molded part, which can be made from plastic, such as PC, PP, PBT, PVC, ABS, PS, PE, PMMA, PET, ASA, CA (Cellulose Acetat), PA (Polyamide), PET, LDPE (Low Density Polyethylene), HDPE (High Density Polyethylene), PPS (Polyphenylene Sulfide), and/or other suitable plastics) and includes retaining clips 256, 258 on top and bottom portions of the handle 250.

At least one of the retaining clips 256, 258 can be a quick release clip, which flexes to allow the handle 250 to be inserted through the hole in the panel 235 and then returns to its original position to attach the handle 250 to the panel 235. In the example shown, the top retaining clip 256 is a quick release clip. Thus, the handle is installed in the panel by inserting the bottom side of the handle through the panel 235 from the exterior side, placing the bottom portion of the retaining edge 254 on the exterior side of the panel 235 and the bottom retaining clip 258 on the interior side of the panel 235, then pushing the top side of the handle 250 through the panel 235 to cause the retaining clip 256 to depress, as the handle 250 is inserted, and then snap back up to secure the handle 250 in place, with all of the retaining edge 254 flush against the exterior side of the panel 235. Note that the construction material used for the handle 250 should have enough flexibility for the retaining clip 256 but also be strong enough to hold the mass of the cabinet when filled with electronics equipment. Other attachment mechanisms are also possible. In addition, note that a sealing gasket is not required between the handle 250 and the side panel 235 since any air that enters around the retaining edge 254 of the handle 250 will still be pulled into the same air channels of the air intake system, as described further below.

As noted above, the opening made for the handle 250 can be taken advantage of to act as a vent that provides an air intake for the cabinet's cooling system. This can be done on one side of the cabinet or on both sides of the cabinet (e.g., the same type of handle design can be used with both the right side panel 235 and the left side panel 230). The handle 250 can include one or more vent holes located in an upper, interior portion of the recessed handle 250, and various designs can be used for these vent hole(s). As the holes are located within the recessed handle, recessed back into the handle top, this provides some level of protection from contamination splashing or falling into the intake vent holes.

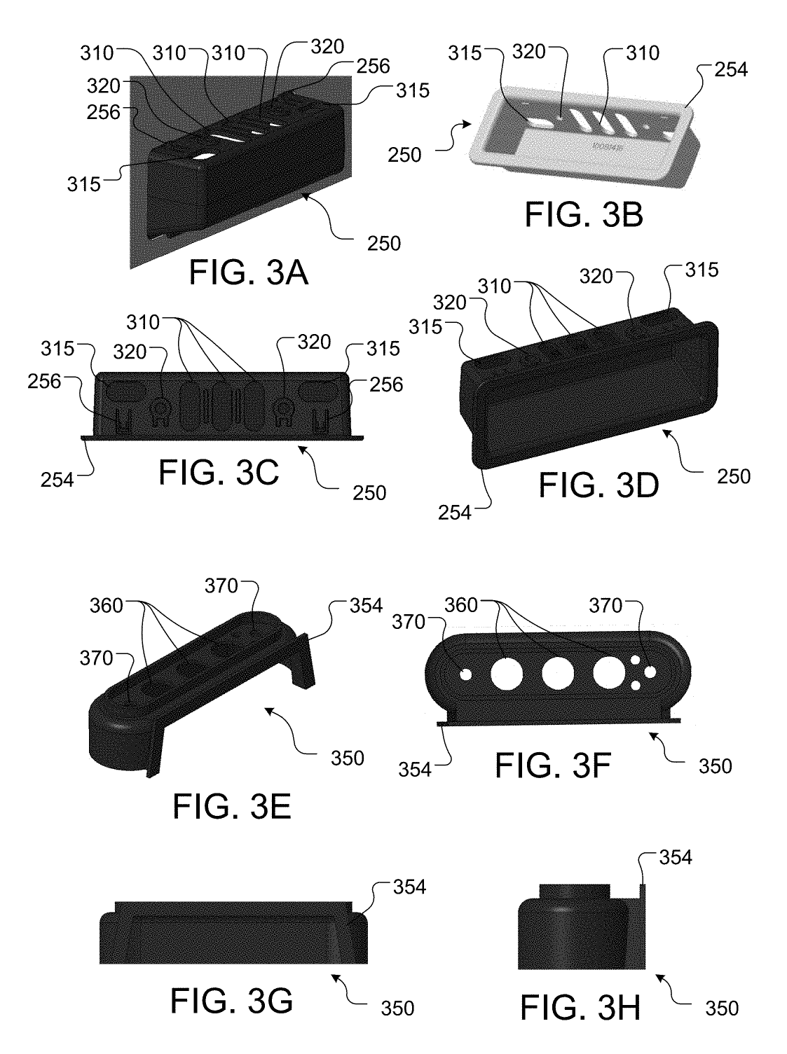

FIG. 3A shows a close-up, perspective view of the handle 250, as shown in FIG. 2C, in place in the side panel. The handle 250 is shaped to define three central vent holes 310. As noted, fewer or more vent holes can be used in various implementations. In this example, the handle 250 further defines two lateral vent holes 315. More and/or larger vent holes is generally better since a larger cross-sectional area for the vent hole(s) makes it easier to pull enough volume of air through the vent handle(s) into the cooling system in the cabinet. But irrespective of the number and size of vent hole(s) in the handle(s), the vent hole(s) can be positioned to be aligned with one or more channels (defined at least in part by the frame) of the air intake system for the cabinet.

In addition, the handle 250 can be shaped to define one or more mounting holes 320 for use in attaching the handle 250 to the frame. For example, two mounting holes 320 can be provided that are sized to receive screws or bolts that mate with threaded receiving holes in the bottom piece 208. Other approaches to attaching the handle to the frame are also possible. In addition, FIG. 3A shows the retaining clips 256 being two quick release clips 256, e.g., created along with the handle 250 using injection molding techniques. These quick release clips 256 flex during installation, as described above.

FIG. 3B is a perspective view showing the handle 250 detached from the side panel. FIG. 3B presents the handle 250 from a position below the handle 250, looking upward into the recessed portion of the handle 250, i.e., the portion that is on the interior side of the side panel once installed therein. This view shows that the vent holes 310, 315 and the mounting holes 320 are in the upper, interior portion of the recessed handle 250. FIG. 3C is a top view of the handle 250. FIG. 3D is a perspective view showing the handle 250 presented from a position above the handle 250, looking downward into the recessed portion of the handle 250.

FIGS. 3E-3H show another example of a vent handle 350 for use with the cabinet in accordance with the present disclosure. FIG. 3E is a perspective view showing the vent handle 350 presented from a position above the handle 350, looking downward onto the recessed portion of the handle 350. FIG. 3F is a top view of the handle 350. FIG. 3G is a front (cabinet exterior side) view of the handle 350, and FIG. 3G is a side view of the handle 350.

The handle 350 is shaped to define three vent holes 360, which can be positioned to be aligned with one or more channels (defined at least in part by the frame) of the air intake system for the cabinet. In addition, the handle 350 is shaped to define two mounting holes 370 for use in attaching the handle 350 to the frame. As before, the two mounting holes 370 can be sized to receive screws or bolts that mate with threaded receiving holes in the bottom piece 208. In addition, the recessed handle 350 does not include retaining clips. Thus, the handle 350 does not explicitly attach to the side panel, but rather only attaches to the frame. Since the recessed handle 350 does not include quick release clips, the construction material used for the handle 350 does not need to provide the flexure noted above, and so more rigid materials can be used.

The recessed handle 350 includes a retaining edge 354 to hold the bottom portion of the side panel to the frame. As shown, the retaining edge 354 extends on only three sides, rather than around the entire circumference of the handle 350. The retaining edge 354 has a trapezoidal shape that matches a cutout portion at the bottom of the side panel. For assembly, the handle 350 is placed onto the bottom piece 208, aligned with the threaded receiving holes, and the screws or bolts go through the mounting holes 370 and are fastened into the bottom piece 208. The side panel (and its corresponding trapezoidal cut-out at the bottom) is raised and then hooked behind the retaining edge 354, where the mass of the side panel is taken by the handle 350. The top of the side panel is then put into position and attached to the frame, such as described in detail below. Note that other designs for the retaining edge and attachment of the handle to the cabinet are also possible.

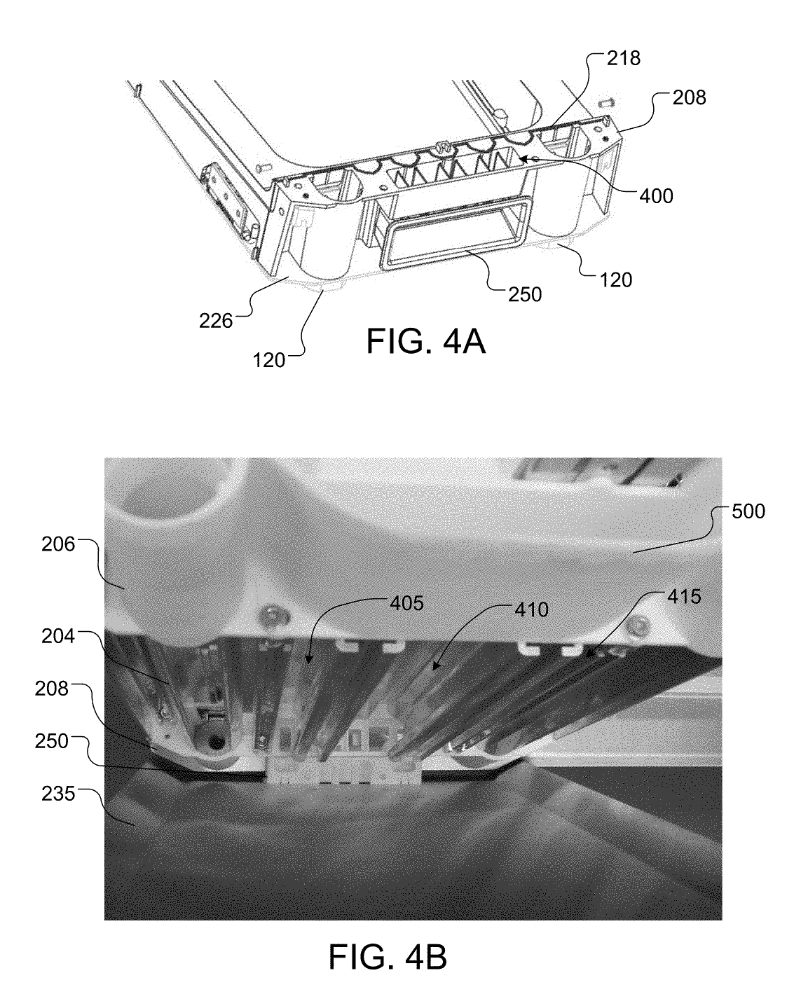

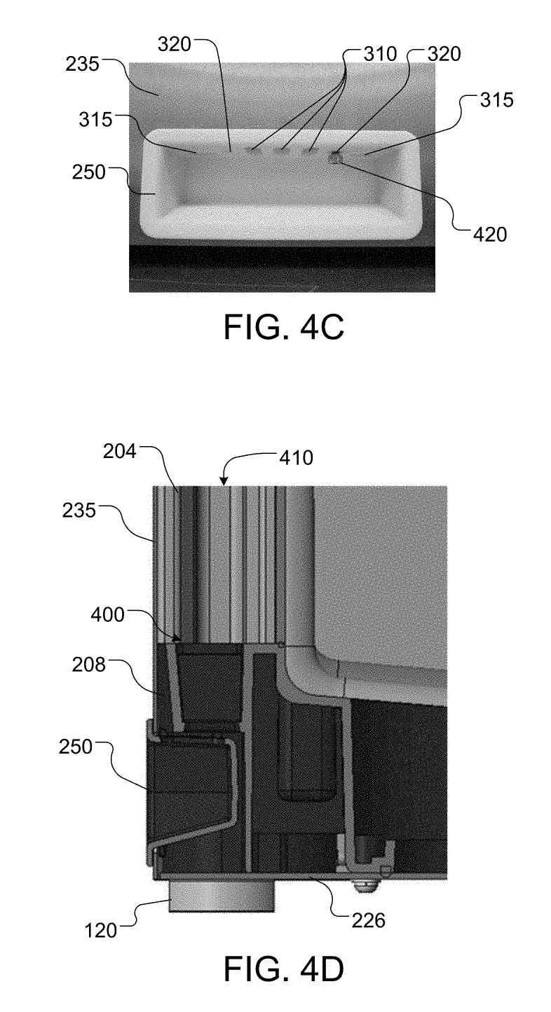

FIG. 4A is a cutaway view of the bottom piece 208 with the vent handle 250 inserted into the bottom piece 208. As shown, the bottom piece 208 has the bottom cover 226 and feet 120 attached, and includes the right side seal 218, but the right side wall 204 is not shown. The bottom piece 208, which is part of the frame, defines at least part of a channel for air coming through the vent handle 250, which has its at least one hole aligned with the channel. In the example shown, in which the vent handle 250 includes five vent holes, the bottom piece 208 defines five channels 400 for air coming through the vent handle 250.

Note that the figure shows seven channels, but two of these correspond to the mounting holes 320, and so only a little air (or in some cases no air) comes through these channels. Nonetheless, it will be appreciated that the cabinet design does not require that the mounting holes 320 be sealed off, since any air flowing through these holes will also pass through one or more channels in the side wall 204 and help with the cooling of the intake air. Thus, the bottom piece 208 can be considered as defining seven channels 400 for air coming through the vent handle 250. Many variations in the number of vent holes, air channels, and degrees of alignment between them are possible. In any case, the vent holes of the handle can take advantage of the mounting holes placed in the frame for the handle, eliminating any need for a second or third set of holes for an air intake, which would be an added path for contamination to enter the cabinet.

FIG. 4B is a cutaway view of the top piece 206, which is attached to the right side wall 204, which is in turn attached to the bottom piece 208. The vent handle 250 is partially inserted into the bottom piece 208, and the interior side of a cutaway portion of the right side panel 235 is shown resting just above the vent handle 250, but not yet attached to the frame. The right side wall 204, which is part of the frame, defines at least part of a channel for air coming through the vent handle 250, which has its at least one hole aligned with the channel. In the example shown, in which the vent handle 250 includes five vent holes, the right side wall 204 defines part of three channels 405, 410, 415.

When the vent handle is fully inserted, the three central vent holes of the vent handle 250 are aligned with a central air channel 410, the left most vent hole of the vent handle 250 is aligned with a left air channel 405, and the right most vent hole of the vent handle 250 is aligned with a right air channel 415. The other part of these three channels 405, 410, 415 is formed by the right side panel 235, when the right side panel 235 is attached to the frame (e.g., to the top piece 206). In other implementations, the air channel(s) in the frame are fully formed by the side wall(s) without using the side panel(s) to complete the air channel(s). In some implementations, one or more of the air channels connect with each other within the side wall to allow for fluid (air) communication between or among the air channels in the side wall (e.g., formed between the right side wall 204 and the right side panel 235). In some implementations, each of the air channels is isolated from each other within the side wall.

Other implementations are also possible. As will be appreciated, many variations are possible in terms of the number of air channels formed by the frame and how those air channels connect with each other and/or with the vent handle(s) and the cabinet's cooling system. In addition, the vent handle 250 can be placed in various locations along the frame, however, it is generally preferable to provide longer air channels in order to increase separation between the air intake point and the air filter (as described in further detail below) and to increase the exposure of the incoming air to a heat sink along the channels, such as a heat sink formed by the side wall (and potentially the side panel when formed of a material, such as aluminum, that can server as a heat sink) to facilitate cooling of the intake air.

In some implementations, the vent handle 250 is located at or near the bottom of the cabinet, as shown, to allow the drawn in air pulled from the top of the cabinet to flow across the entire length (or nearly the entire length) of the side wall 204, which serves as the heat sink. For example, when using a metal side wall (e.g., an extruded aluminum side wall) as the heat sink, providing vertical air channel(s) that span the full length (or near to the full length) of the side wall facilitates convectional cooling of the air that is drawn through the vent handle and into the wall of the cabinet. In any case, at least one of the frame's air channels should allow air to flow into the cooling system for the cabinet. For example, when the cooling system includes an air filtering system, at least one of the air channels in the frame should allow fluid (air) communication between the vent handle 250 and a filter assembly pocket 500 built into the top piece 206.

FIG. 4C is a cutaway view of the right side panel 235 with the vent handle 250 fully inserted into the frame (not shown). The vent handle 250 includes the vent holes 310, 315 and the mounting holes 320, as described above. In addition, a screw or bolt 420 is shown in the right most mounting hole 320, in the process of being screwed into the frame. FIG. 4D shows a cutaway, cross-sectional view of the cabinet with the handle 250 mounted to the bottom piece 208, and the side panel 235 mounted to the frame, thereby forming air channels 410 in combination with the side wall 204. As will be appreciated, and comparing FIGS. 4B-4D, when the vent handle 250 is fully installed, the three central vent holes 320 align with the central air channel 410, the left and right vent holes 315 align with the left and right air channels 405 and 415, respectively, and the vent handle 250 acts as a retaining edge for the bottom of the side panel 235 (which is mounted above the handle) holding the bottom of the side panel 235 to the frame when the handle 250 is attached to the frame using screw(s)) or bolt(s) 420.

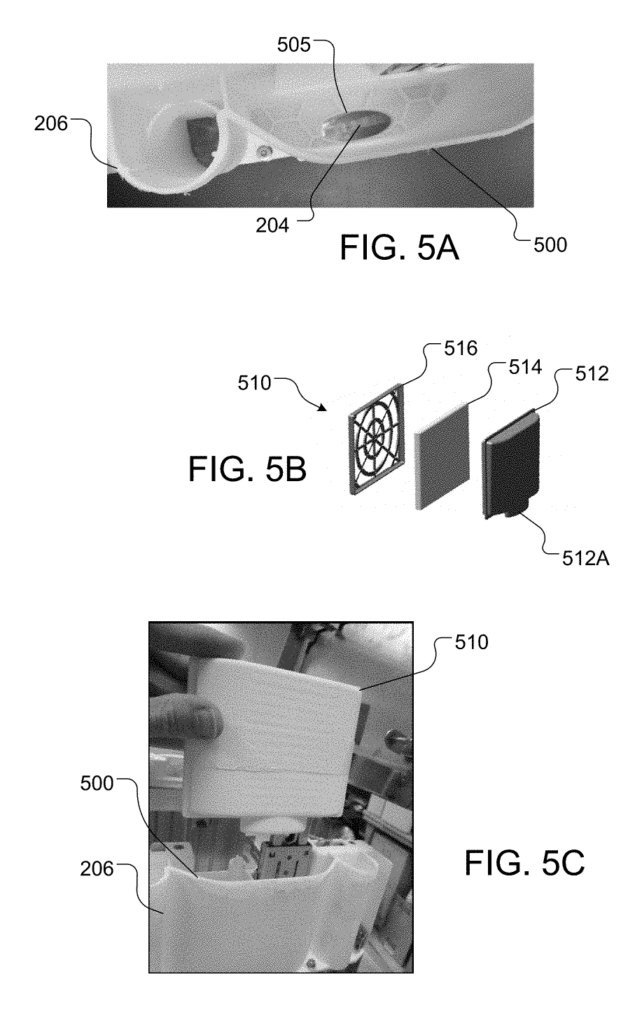

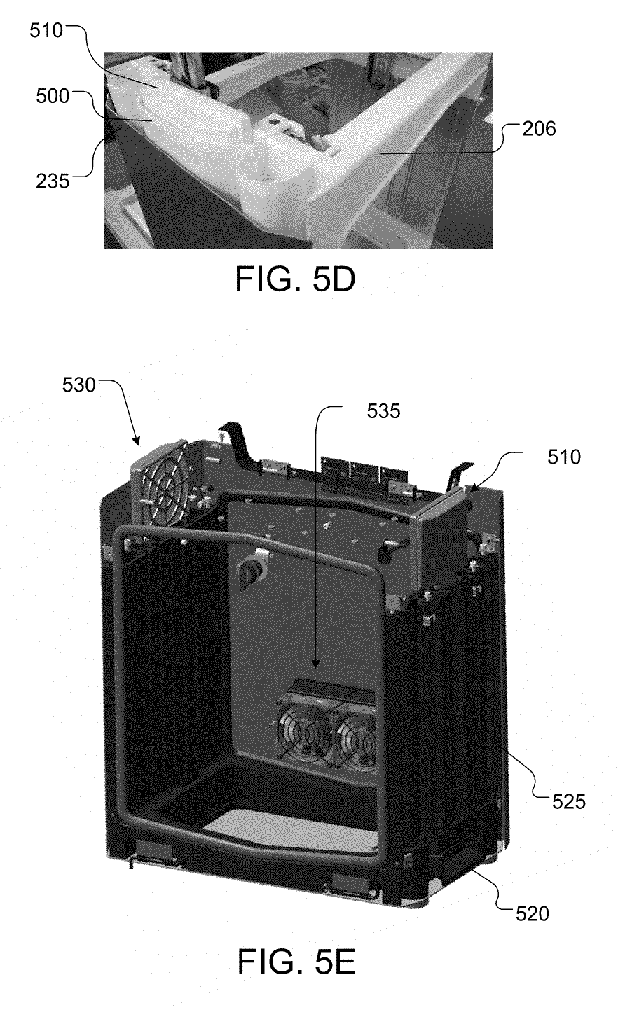

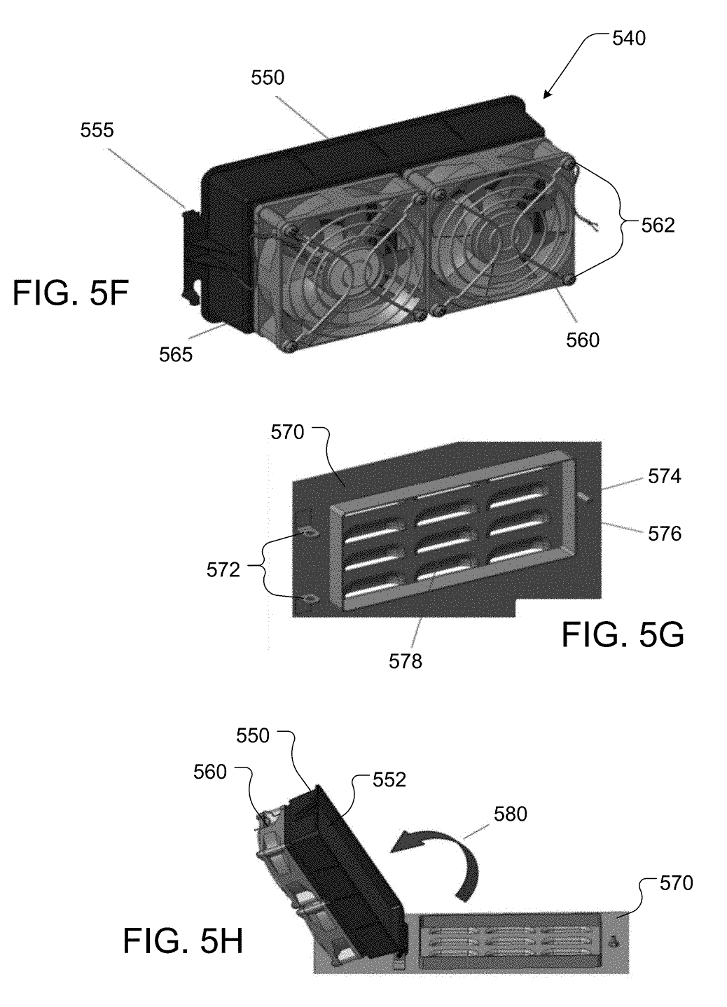

The air intake systems and techniques described herein can be used with various types of filtering and/or cooling structures within the cabinet or control box. An example of modular filter and fan cooling assemblies is now described, but many variations and alternative configurations for the cabinet's internal structures are possible. FIG. 5A shows a cutaway (top down) view of the top piece 206 with the built-in filter assembly pocket 500. At the bottom of the filter assembly pocket 500 is an opening 505, e.g., an oval shaped opening, as shown, or another shape.

Through the opening 505 can be seen a portion of the side wall 204, and the opening 505 provides a fluid (air) coupling to the air channel(s) in the side wall 204. Thus, the opening 505 is the location where air that has passed over the side wall/heat sink 204 is pulled into the controller cabinet. Preferably, this air is filtered before it is allowed into the cabinet's interior, and because of the placement of the filter pocket 500 at the top of cabinet (with the air intakes toward the bottom of the cabinet) the filter media is protected from water and liquid damage in a wash-down environment by the distance against gravity that needs to be traveled from the bottom of the cabinet to the top within the wall of the frame.

FIG. 5B shows an example of a removable filter assembly 510. The removable filter assembly 510 includes a core module 512, which includes a bottom opening 512A with a shape that matches to the opening 505. The removable filter assembly 510 also includes a replaceable filter media module 514 and a cover module 516. The core and cover modules 512, 516 can be made of plastic, such as PC, PP, PBT, PVC, ABS, PS, PE, PMMA, PET, ASA, CA, PA, PET, LDPE, HDPE, PPS, and/or other suitable plastics, and the replaceable filter media module 514 will be constructed in accordance with the filtering requirements for the electronics to be placed inside the cabinet. As will be appreciated, when the filter media 514 needs to be replaced after extended use, it is straight forward to raise the top of the cabinet, pull out the removable filter assembly 510, disassemble (without tools) the removable filter assembly 510 into its sub-modules, replace the filter media module 514, and then reassemble (without tools) the filter assembly 510.

FIG. 5C shows a person inserting the removable filter assembly 510 back into the filter assembly pocket 500 in the top piece 206. FIG. 5D shows the removable filter assembly 510 fully inserted into the filter assembly pocket 500 in the top piece 206. The side wall 235 is also shown in FIG. 5D, but the top cover and front and back panels are removed. FIG. 5E shows an example cabinet with various components eliminated in order to facilitate understanding how air flows into and within the cabinet.

The cabinet shown in FIG. 5E includes a vent handle 520, an extruded aluminum side wall 525, and the filter assembly 510. The side panel, front panel, top piece and top cover are removed in the figure. The cabinet includes a second air intake/cooling/filtering system 530 on the other side of the cabinet, where the air intake/cooling/filtering system 530 also includes a vent handle (not shown), an extruded (heat sink) side wall, and a removable filter assembly. In addition, a fan system 535 can be used to expel air from the back side of the cabinet and correspondingly pull fresh air into the cabinet.

Air is pulled through the vent holes in the handles (e.g., through handle 520) into the air channels formed between the side walls and the side panels/dressings. The air is cooled as it passes along the extruded metal side walls (e.g., along extruded aluminum side wall 525) and then passes through the two filters (e.g., through filter assembly 510) before entering the interior of the cabinet. The filtered air can then circulate within the cabinet to cool the electronics (not shown) before passing out of the cabinet through the fan system 535. Note that the cool air enters at the top of the cabinet, and expelled air is removed at the bottom of the cabinet, which can facilitate mixing and circulation of the air within the cabinet.

In some implementations, the fan system 535 is a modular fan cooling assembly. The cabinet system can be designed to house many different types of electronics, and thus can be understood as a modular control box, i.e., a cabinet that can be used across a range of product technologies. But different product technologies will typically have different cooling requirements. Thus, providing a modular fan cooling assembly allows for the customization of cooling options based on the technology in the control box.

FIG. 5F shows an example of a modular fan cooling assembly 540. The modular fan cooling assembly 540 includes a single holder 550 for one or more fans 560. The single holder 550 can include a hinge 555 to allow quick access to a filter media and also includes matting threads to receive screws or bolts 562 to hold one or more fans to the holder 550. The design of the modular fan cooling assembly 540 allows future adopters to have a choice of the number of modules required, module positions, fan selection with limitations, number of fans, type of filter media and vent design. The holder 550 can be designed to receive fans of different sizes and power levels. In some implementations, the single holder 550 is designed to remove gaps 565 around the edges of the fans.

FIG. 5G is a cutaway view of a cabinet's back panel 570, which has been designed to receive the single holder 550. The back panel 570 includes receiving brackets 572 for the hinge 555. The back panel 570 also includes at least one attachment point for the other side of the holder 550, such as a single threaded stud 574 welded to the back panel 570. Further, the back panel 570 can include a fully welded rib 576 to apply pressure to the filter media when the modular fan cooling assembly 540 is in place, and to maintain the internal air pressure of the cabinet, which is controlled by the fans 560. Note that exhaust vents 578 can be customized to meet future adopter needs. Moreover, the modular fan assembly allows future adopters to place the module on any external panel by moving the noted features, or include more than one such module, which allows future adopters to have more air flow and/or control the path of air into the cabinet, as desirable for a particular application.

FIG. 5H shows the single holder 550 with two fans 560 attached, and the single holder 550 is attached to the back panel 570 on the hinged side, but has been detached from the back panel 570 on the other side (e.g., by unscrewing a single nut from the single threaded stud 574). Thus, the single holder 550 is rotated 580 away from the back panel 570 while still being attached to the back panel 570, and this provides easy access to the filter media 552 placed within the single holder 550, and so the filter media 552 can be readily replaced when needed. Thus, the design prevents the need for engineers to remove the module 550 or fans 560 to change the filter media 552.

Note that exhaust fan filters do not necessarily need to be changed regularly. However, the modular fan assembly 540 design can be used for air inlet or outlet flow. The modular fan assembly 540 has a small foot print and can be cleaned easily. In addition, the modular fan assembly 540 is low cost compared with existing, off the shelf filter modules.

Returning to the air intake system for the cabinet, as noted above, the air intake system can also cool the air using metal side walls (e.g., extruded aluminum side walls) to form at least a portion of the air channels for the incoming air. In addition, these metal side walls can be designed to provide a reconfigurable mounting system for the cabinet. The following description provides detailed examples of extruded aluminum side walls that provide both a reconfigurable mounting system for the cabinet and also act as a heat sink within the air intake system for the cabinet. However, it will be appreciated that metal side walls constructed by welding and/or bolting together appropriately sized and shaped pieces of metal can also provide the reconfigurable mounting system and heat sink described below (e.g., a main side wall shape formed from sheet metal with separately manufactured T-slots bolted thereto).

Moreover, it should be understood that the reconfigurable mounting system can be implemented in a cabinet without also using the side walls as part of the air intake/cooling/filtering system. Thus, when the side walls are not a heat sink, they need not be made of metal, let alone extruded aluminum. However, there are advantages to using extruded aluminum side walls in terms of cost of production and strength to weight ratio for the cabinet, and there are advantages to using metal side walls (e.g., extruded aluminum side walls) to provide dual functions as a structure for mounting electronics (or other items) to the cabinet (interior and/or exterior) and as a heat sink for an air intake/cooling/filtering system.

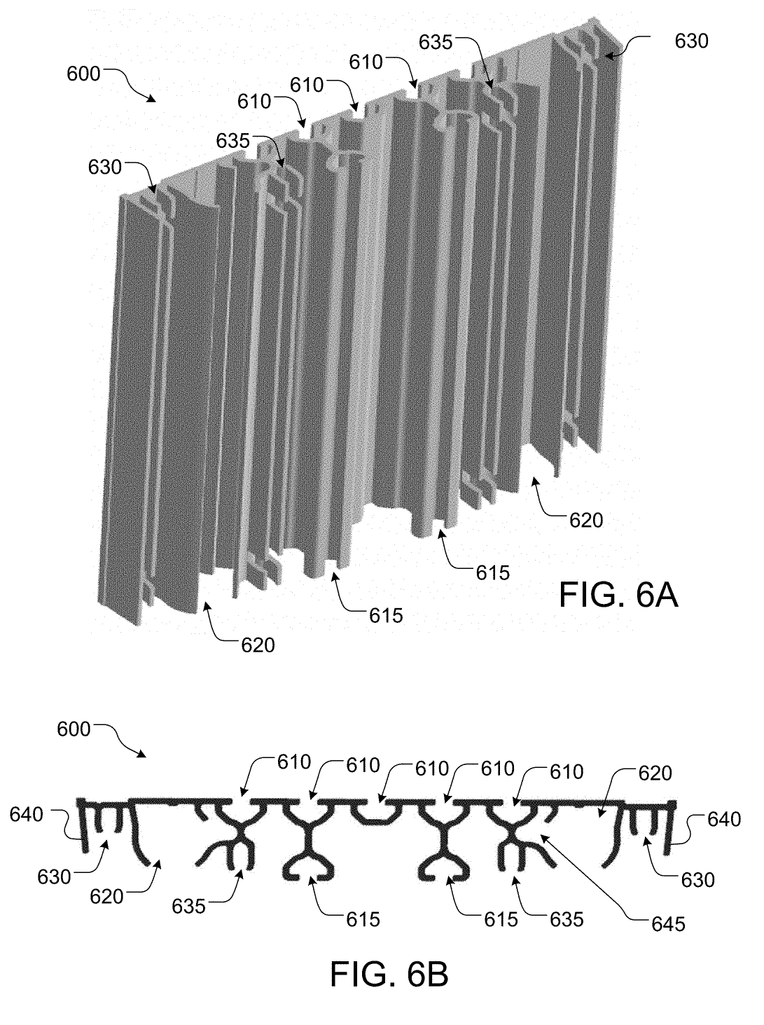

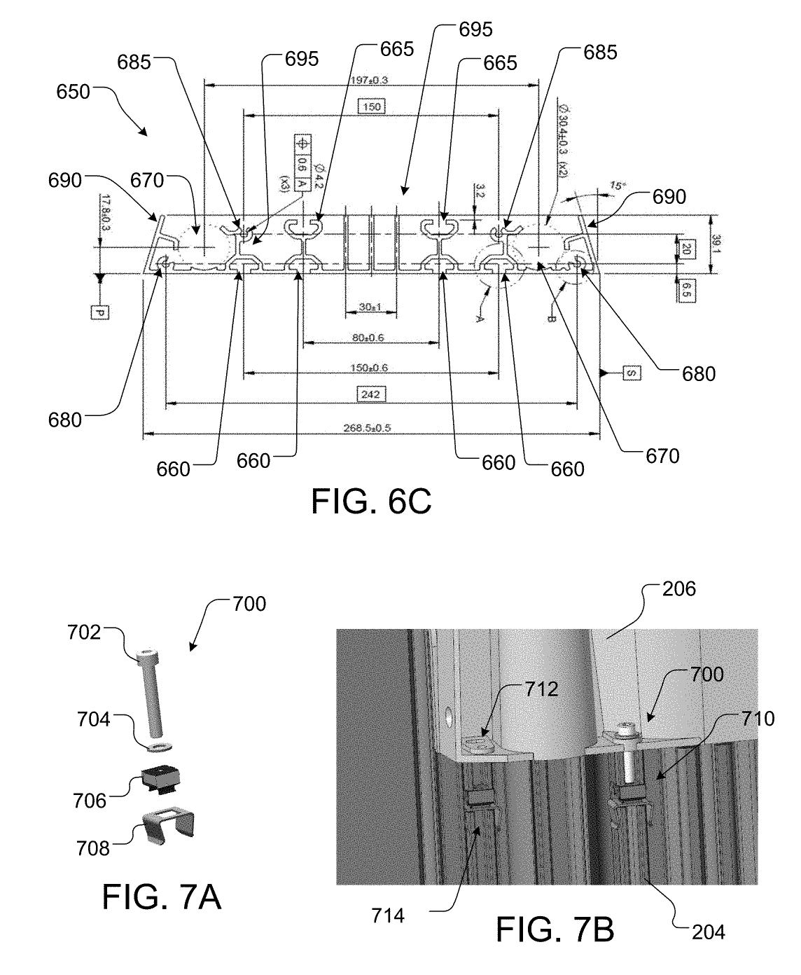

FIG. 6A is a perspective view of an example of an extruded aluminum side wall 600 (other metals, such as stainless steel, can also be used, as noted above), which can be used to form opposite sides of a cabinet frame, as described above. FIG. 6B is a top side view of the extruded side wall 600. The side wall 600 defines a shape, as shown, that receives a structure to support the cabinet and also receives fasteners on both sides of the side wall 600 to mount equipment on both an interior portion of the frame and an exterior portion of the frame. Thus, the design of the extrusion shape incorporates features for both internal and external cabinet mounting.

In the example shown, the shape of the extruded side wall 600, which is the side wall structure able to receive the fasteners on both sides of the wall, constitutes multiple T-slots 610, 615 (e.g., Bosch mounting slots). In this example, there are five T-slots 610 on an interior side of the extruded side wall 600, and there are two T-slots 615 on an exterior side of the extruded side wall 600. Different numbers of T-slots (and potentially different lengths and positions of T-slots than shown) can be included on the two sides of the extruded side wall 600. Moreover, as used herein, the term “T-slot” does not require a shape that explicitly looks like the letter T; rather, any slot having a narrower entrance to a wider interior space, thereby forming a structure that provides multiple (e.g., continuous) mounting points along the slot, constitutes a T-slot. Thus, the T-slots can have various different interior shapes, such as half-moon, round, square, dove tail, etc. In any case, the use of T-slots can provide significant benefits in terms of versatility of the mounting locations for equipment, both inside and outside the cabinet, as well as being relatively easy to construct using metal (e.g., aluminum) extrusion processes.

In addition, the lateral distances between the T-slots 610, 615 can be standardized to increase the usability of the mounting system, and more than one standardized distance can be used on the interior and/or exterior sides of the side wall. In the example side wall 600, the lateral distance between the two external T-slots 615 is equivalent to the lateral distance between the first and third of the five internal T-slots 610, which is equivalent to the lateral distance between the second and fourth of the five internal T-slots 610, which is equivalent to the lateral distance between the third and fifth of the five internal T-slots 610. In some implementations, the internal T-slots 610 have 30 mm between their centers, and the external T-slots 615 have 60 mm between their centers. Regardless of the number and placements of the internal T-slots 610 and the external T-slots 615 provided in a given implementation, the internal T-slot channels in the side wall shape can be used to mount the internal components to the cabinet, and the external T-slot channels in the side wall shape can be used to mount accessories to the cabinet and/or to mount the cabinet to a larger piece of equipment such as a packaging machine.

In addition, in this example, the shape of the extruded side wall 600 that is the side wall structure able to receive another structure to support the cabinet constitutes tube slots 620. These slots 620 (or holes) are sized to interchangeably receive feet structures (e.g., feet 120) or pillar structures. Further, the top and bottom pieces preferably include tube slots that generally align with the tube slots 620. More details regarding examples for using these tube slots are provided below.

In addition, the shape of the extruded side wall 600 can include additional structural features used to facilitate assembly of the cabinet. For example, the shape of the extruded side wall 600 can include mounting locations 630, 635 for attaching the top and bottom pieces of the cabinet to the side wall (as described in further detail below). The shape of the extruded side wall 600 can include additional side fins 640 to assist in heat dissipation in implementations where the side wall 600 serves as a heat sink (note that additional components can be used to improve heat dissipation, such as coupling a heat pump to the side wall 600 to chill the metal of the side wall 600). Further, the shape of the extruded side wall 600 can include a profile 645 that receives a cable and grommet (e.g., for electrical wiring to be placed between the side wall and the side panel/dressing during assembly of the cabinet).

Moreover, as will be appreciated, the shape of the side wall can be readily changed, and need not have the attractive sinuous appearance of the example side wall 600. FIG. 6C is a top side view of another example of an extruded side wall 650. In this example, the shape of the extruded side wall 650 that is the side wall structure able to receive the fasteners on both sides of the wall constitutes multiple T-slots 660, 665 (e.g., Bosch mounting slots). In this example, there are four T-slots 660 on an interior side of the extruded side wall 650, and there are two T-slots 665 on an exterior side of the extruded side wall 650. But as before, different numbers of mounting points can be included on the two sides of the extruded side wall 650, these mounting points can have different shapes, other than T-slots, the lateral distances between the T-slots 660, 665 can be standardized to increase the usability of the mounting system, and more than one standardized distance can be used on the interior and/or exterior sides of the side wall.

In addition, in this example, the shape of the extruded side wall 650 that is the side wall structure able to receive another structure to support the cabinet constitutes tube slots 670. These slots 670 (or holes) are sized to interchangeably receive feet structures (e.g., feet 120) or pillar structures (as described in further detail below). In addition, the shape of the extruded side wall 650 can include additional structural features used to facilitate assembly of the cabinet. For example, the shape of the extruded side wall 650 can include mounting locations 680, 685 for attaching the top and bottom pieces of the cabinet to the side wall. The shape of the extruded side wall 650 can include additional side fins 690 to assist in heat dissipation in implementations where the side wall 650 serves as a heat sink (additional components can also be used to improve heat dissipation, as noted above). Further, the shape of the extruded side wall 650 can include a profile 695 that receives a cable and grommet (e.g., for electrical wiring to be placed between the side wall and the side panel/dressing during assembly of the cabinet).

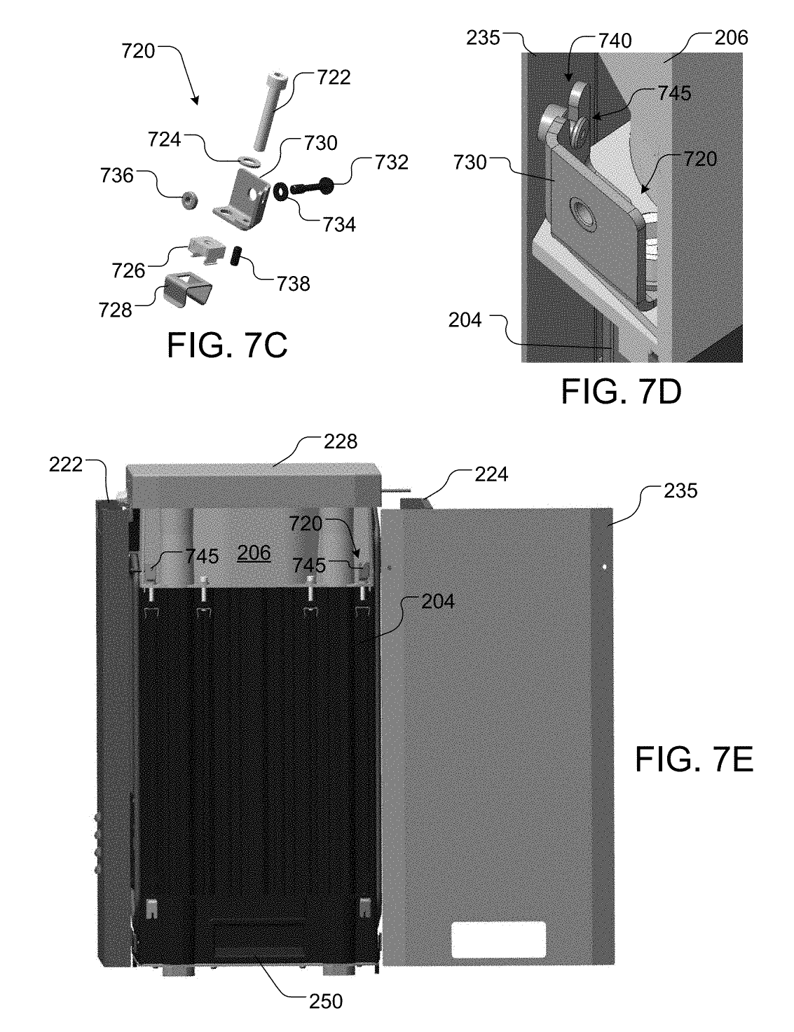

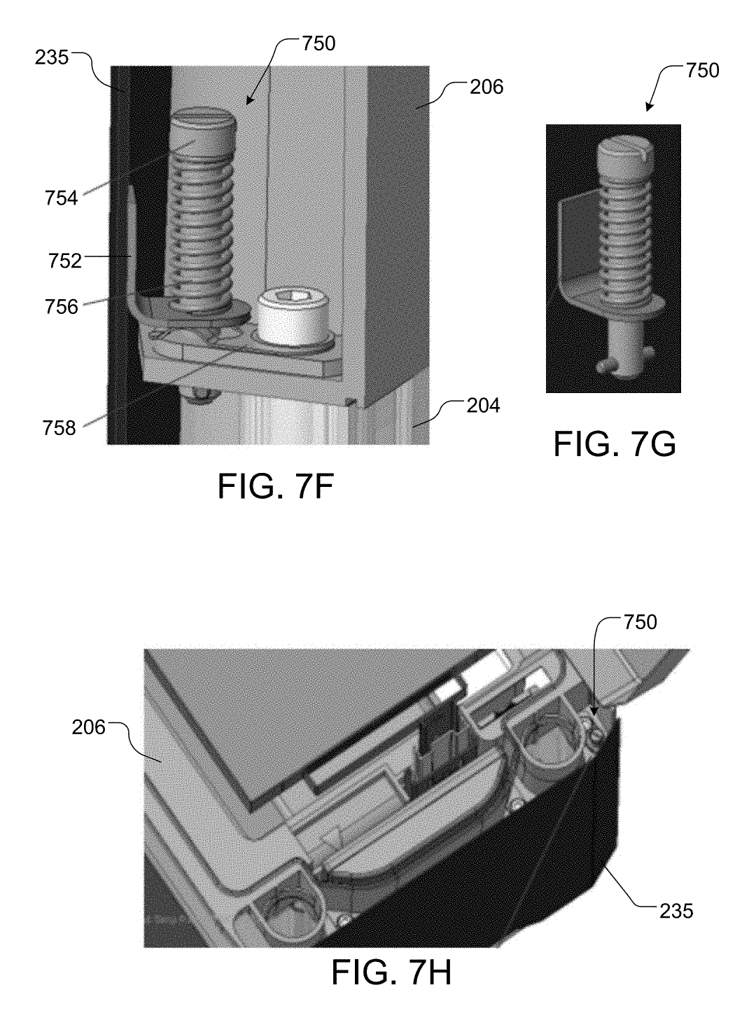

FIG. 7A shows an example of a connector assembly 700 that can be used to attach top and bottom pieces of the cabinet to the side wall, e.g., to affix the top piece 206 to the extruded side wall 204. The connector assembly 700 is a cage nut assembly, which includes a screw or bolt 702 (e.g., an M5x30 screw), a washer 704, a cage nut 706 (e.g., an M4 cage nut), and a cage nut clip 708. FIG. 7B is a cutaway view of an example of the cabinet, showing an example of the cage nut assembly 700 affixing the top piece 206 to the side wall 204. As shown, the cage nut 706 is inserted into a cutout portion 710 (a cutout notch or pocket) of the extruded shape of the side wall 204, and the cage nut clip 708 is also inserted into this cutout portion 710 of the side wall's shape, and also has its brackets (on either side of the ‘U’ shape of the clip 708) located on either side of the extrusion shape that receives the screw or bolt 702.

Using this cage nut configuration to secure an extruded aluminum side wall to the plastic parts of the cabinet (e.g., to the top piece 206) helps to prevent the attachment assembly from being over constrained. For the assembly of the cabinet frame, the technology tolerances of the various parts should be taken into account. For example, extruded metal parts often have a manufacturing tolerance of +1.5 mm, whereas plastic parts often have a manufacturing tolerance of +0.4 mm. To be able to manage these tolerances and to reduce or minimize the machining operations employed on the extruded profile of the side wall, the U clip 708 and cage nut 706 are used to facilitate the attachment of metal to plastic parts, rather than adding a cylindrical column into the extrusion shape and tapping it so that a screw can be threaded into it later.

The plastic part (e.g., the top piece 206) can include oblong holes 712 to receive the screws or bolts 702, and the washers 704 hold the screws or bolts 702 in place above these holes. This allows for some movement of the screws within the plastic, which facilitates connections despite differences in expected sizes of the respective parts. In addition, by matching the size of the U clips 708 to the extrusion profile size, including the cutout portion 710 thereof, the U clips 708 help secure the cage nuts 706 to the extrusion profile even before the screws or bolts 702 are attached, as shown at 714. Using the U clips 708 with floating cage nuts 706 provides an “adjustable nut” for receiving the screw, which facilitates the handling of differences in expected sizes of the respective parts.

The design helps with aligning the two different material parts with different tolerances together without the added need for machining to correct for tolerance differences. Any tolerance mismatching can be compensated for with the oblong holes in the plastic piece, the metal clip at the base of the screw and the cage nut. This facilitates quick connection of two different tolerance parts without the need for an added tooling operation or for fixed tapped fastening holes. Thus, the design also simplifies assembly of the cabinet overall. In addition, note that variations in this design can also be made, in different implementations or in the same implementation, including the use of one or more additional connectors with the cage nut assembly.

FIG. 7C shows another example of a connector assembly 720, which can be used to attach a top piece of the cabinet to the side wall, e.g., to affix the top piece 206 to the extruded side wall 204, and also to connect the side panel (e.g., right side panel 235) to the frame formed by the top and bottom pieces plus the two side walls. The connector assembly 720 includes a cage nut assembly, which includes a screw or bolt 722 (e.g., an M5x30 screw), a washer 724, a cage nut 726 (e.g., an M4 cage nut), and a cage nut clip 728. The connector assembly 720 includes a connector for use in attaching a side panel/dressing of the cabinet. In this example, the connector is a “Multi Earth” bracket 730, plus a captive screw 732 (e.g., an M4x20 captive screw), a captive washer 734 (e.g., an M4 captive washer), a clinch nut 736 (e.g., an M4 clinch nut), and a spring pin 738 (e.g., a 3×6 spring pin).

FIG. 7D is a cutaway view of an example of the cabinet, showing an example of the cage nut assembly 720 affixing the top piece 206 to the side wall 204. As before, the cage nut 726 is inserted into a cutout portion (a cutout notch or pocket) of the extruded shape of the side wall 204, and the cage nut clip 728 is also inserted into this cutout portion of the side wall's shape, and also has its brackets (on either side of the ‘U’ shape of the clip 728) located on either side of the extrusion shape that receives the screw or bolt 722.

In addition, the bracket 730 includes a keyhole slot 740 that mates with a pin 745 located at a top portion of a side panel (e.g., side panel 235, as shown). Using such pins 745 facilitates the attachment of the side panel to the frame. FIG. 7E shows an example of the cabinet, with the front panel 222, the back panel 224, the top cover 228, and the handle 250, as described above. In addition, the right side panel 235 has been removed from its pins 745 and set to the right of the cabinet in the figure (the holes shown in the side panel 235 correspond to the pins 745 that attach to the side panel 235 at these locations) in order to show the spatial relationship between the side panel 235 and the connectors used to attach the side panel 235 to the frame. Referring to both FIG. 7E and FIG. 4B, the side panel 235 is attached to the frame by sliding the pins 745 on the panel 235 into the keyhole slots 740, with which they mate, and then inserting the handle 250 into the vent cut out at the bottom of the panel 235, and using screws to attach the handle 250 to the bottom piece of the frame. In this example, the handle 250 includes a retaining edge that holds the side panel 235 to the frame at the bottom of the side panel 235, and the pins 745 hold the side panel 235 to the frame at the top of the side panel 235.

Other connector structures can also be used to attach the cabinet panels to the frame. For example, FIG. 7F is a cutaway view of the frame (the top piece 206 attached with the side wall 204 using a cage nut assembly, as described above) with the side panel 235 being attached using a quick release assembly 750. FIG. 7G also shows the quick release assembly 750, but with the quick release assembly 750 being detached from the frame (e.g., decoupled from the hole in the top piece 206).

The quick release assembly 750 includes a bracket 752 that is welded to the side panel 235. The quick release assembly 750 further includes a pin 754, a spiral spring 756, and a leaf spring 758 between the screw or bolt of the cage nut assembly (which attached the top piece 206 to the extruded side wall 204) and the side panel 235. The spiral spring 756 provides downward force onto the side panel 235 (through the welded bracket 752), and the panel 235 is attached to the frame by pushing the pin 754 down until it passes through a hole in the plastic of top piece 206, which in turn compresses the spiral spring 756. The pin 754 is then rotated (e.g., by ninety degrees, either by hand or using a screw driver and a slot in an upper portion of the pin 754, as shown) and released to lock the panel 235 in place. This action is done in two location at the top of the panel 235. Leaf spring 758 is used to take up the tolerance of the welding and can also serve to make earth continuity between the panel 235 and the extruded side wall 204 (through the cage nut assembly).

FIG. 7H is a cutaway view of an example of the cabinet with the quick release assembly 750 being used to hold the top of the side panel 235 to the top piece 206 of the cabinet frame. As shown, once the top cover of the cabinet is lifted up (or off), the quick release assembly 750 is readily accessible, and can be manipulated to detach the side panel 235 by pushing the pin 754 down, turning it ninety degrees to unlock the pin 754 from the top piece 206, and then pulling the pin 754 back through the plastic of top piece 206 to fully disconnect the top of the side panel 235 from top piece 206. There can of course be two such quick release assemblies on either side of the frame, and both can be manipulated to detach the top of the panel 235. Further, as will be appreciated, the quick release assemblies 750 can be readily manipulated to reattach the side panel 235.

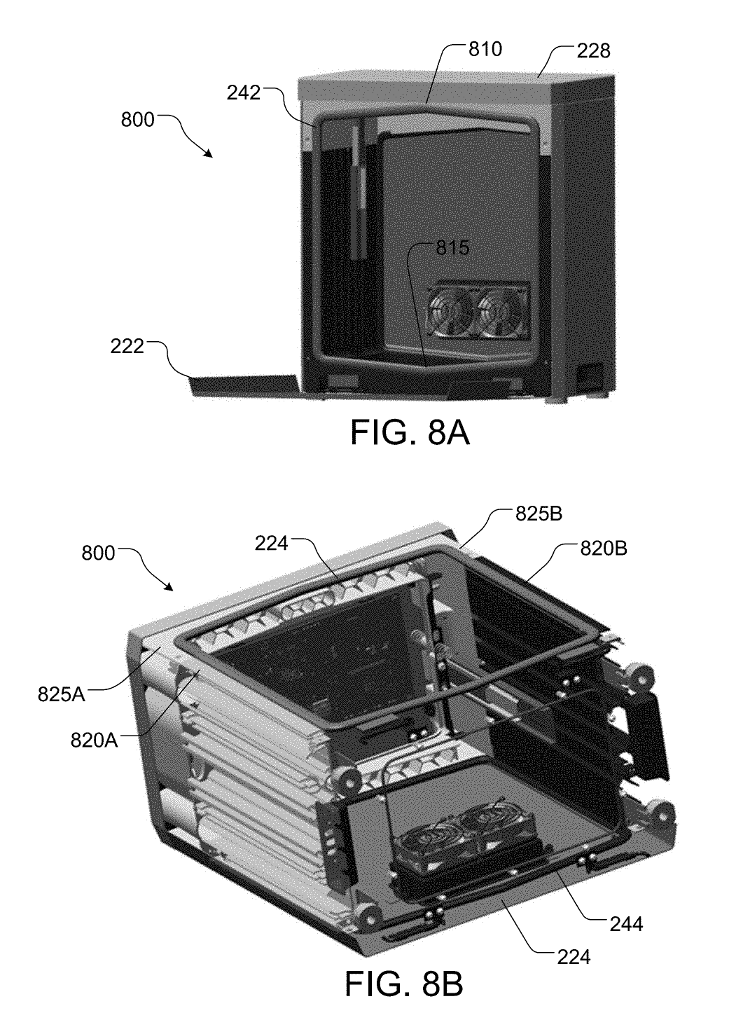

FIGS. 8A & 8B show examples of gasket and frame designs that assist with drainage from an electronics cabinet in a wash-down environment. A cabinet 800 can correspond to the cabinet described in connection with FIG. 2A. Thus, the cabinet 800 includes the front gasket 242 that is compressed between the frame and the front panel 222 when the front panel 222 is closed and attached to the frame, thereby creating a barrier for contaminants that might otherwise get into the interior of the cabinet 800 through the front side of the frame. As shown, rather than use a flat profile for the seal with the door, an ‘A’ frame shape can be used.

Thus, the gasket (or seal) 242 includes a pitched top portion 810, which can be located in the center of the top side of the gasket 242 or offset therefrom to either one side or the other. In general, a steeper pitch of the pitched top portion 810 is better, as this will improve water flow along the top of the gasket 242, but a steeper pitch also reduces the maximum size of the opening into the interior of the cabinet relative to the size of the cabinet. In some implementations, the internal (downward facing) angle of the pitched top portion 810 is between one hundred and seventy five degrees and one hundred and fifty five degrees, e.g., one hundred and sixty five degrees, but smaller internal angles are also possible, e.g., one hundred and forty five degrees or one hundred and thirty five degrees. The gasket (or seal) 242 can be a rubber or foam sealing member that extends entirely around the front opening of the cabinet, but need not track the exact perimeter of the opening, as long as it makes contact with the door 222 when closed. When the cabinet 800 is installed (or mounted) in the vertical orientation (as shown), any liquid that is jetted onto the cabinet 800, and that can get into the groove between the (closed) front panel 222 and the top cover 228, will reliably empty out of the groove above the door since the pitched top portion 810 causes the liquid to naturally flow to the sides in response to gravity, and then run off the edge of the gasket 242 and finally out of the control box 800 at its bottom.

During the cleaning process any water soluble solids will also be forced out through the cleaning wash-down process. Thus, the chances of food (or other solids) being trapped by the gasket 242, which risks bacteria growth, are substantially reduced. The gasket 242 can be made using the foam in place gasket method where the seal is applied in a liquid form from a robotic dispenser following the shape that was programmed. Note that the time to make the ‘A’ frame design is the same as it would be for the traditional rectangular door seal.

Moreover, the ‘A’ frame design can be duplicated on the bottom side of the front gasket 242 by including a pitched bottom portion 815 for the gasket (or seal) 242. The pitched bottom portion 815 can be located in the center of the bottom side of the gasket 242 (as shown) or offset therefrom to either one side or the other, as described above for the pitched top portion 810. In the example shown, the internal angle of the pitched bottom portion 815 is the same as the internal angle of the pitched top portion 810, but in some implementations, different angles can be used for the two pitched portions 810, 815 of the gasket in a given cabinet design. The drainage of water around the cabinet seal 242 is also facilitated by this pitched bottom portion 815, even when the cabinet 800 is installed (or mounted) in the vertical orientation (as shown) since any liquid that runs along the bottom side of the seal 242 will tend to accumulate at the pitched bottom portion 815, thereby facilitating the flow of the liquid off of the seal 242. This design is also helpful if the cabinet 800 may be installed (or mounted) upside down.

The gasket design can also be applied to the back gasket (or seal) 244 (as shown in FIG. 2A). This includes providing a pitched top portion, a pitched bottom portion, or both for the back gasket (or seal) 244, which is compressed between the frame and the back panel 224 when the back panel 224 is attached to the frame, thereby creating a barrier for contaminants that might otherwise get into the interior of the cabinet through the back side of the frame. Moreover, in addition to using the shape of the door seal to improve wash-down conditions, other design features can be applied to the cabinet 800 to help with the Ingress Protection (IP) rating of the cabinet 800.

FIG. 8B shows the cabinet 800 having been installed (or mounted) in a horizontal position (e.g., on its back side). To facilitate drainage from the cabinet 800 in a wash-down environment, the edges of the frame of the cabinet 800 can be angled liked the roof of a house. Examples of this angling is shown in FIGS. 6B & 6C, where the extruded side wall has side fins 640, 690 that are angled rather than straight. In the example of FIG. 6C, the angle is shown as being fifteen degrees, but other angles are also possible. In FIG. 8B, angled side fins 820A, 820B on the respective side walls correspond to side fins 640 in FIG. 6B. In addition, since the side walls only form part of the frame, this angled edge can be extended to the top and bottom pieces, e.g., the molded plastic pieces, such as by angled edges 825A, 825B.

This angling of the exterior edges of the frame helps to direct the flow of any liquid away from the seal 224, which can improve overall drainage and help prevent buildup of contaminants (e.g., food or liquids) along the edge of the seal 224. This angling can also be applied to the opposite side of the frame, corresponding to the back side of the cabinet 800, as shown in FIGS. 6B, 6C, and 8B. Moreover, as will be appreciated, this structural design for the frame can be employed in other implementations that do not use extruded metal side walls and molded plastic top and bottom pieces to construct the frame of the cabinet. In general, one or more (or all) exterior edges of a cabinet frame that are adjacent to a gasket or seal for an access door or panel (to the interior of the cabinet) can be angled with respect to a horizontal plane of the gasket or seal in order to cause liquids to flow away from the gasket or seal due to gravity.

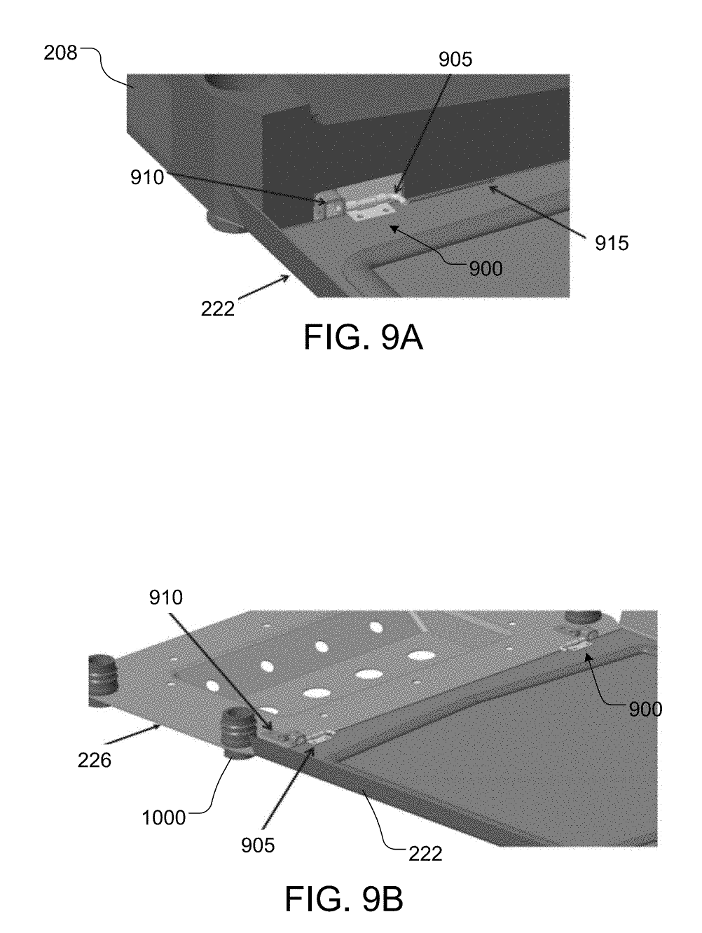

FIG. 9A is a cutaway view of a cabinet showing an example of a quick mount/release fastener 900, as can be used with access doors of electronics cabinets. In the example shown in FIGS. 9A & 9B, the quick mount/release fastener 900 is used to connect the front panel 222 (which is currently open) with the bottom cover 226, which is in turn attached to the bottom piece 208. However, as will be appreciated, the quick mount/release fastener 900 can be used with various other types of cabinets, and need not be used with the cabinet designs described above. Moreover, the quick mount/release fastener 900 can be used with additional cabinet doors (e.g., side or back panels). Note that the ability to quickly change out one or more side panels of an electronics cabinet using the quick mount/release fastener 900 facilitates changing the rated environment in which the electronics cabinet can operate since the outer enclosure of the cabinet (referred to as skins, panels or dressings) can be readily changed, as desired.

The quick mount/release fastener 900 includes a quick release hinge 905 and a pivot bracket 910. FIG. 9B is a cutaway view of the cabinet with the bottom piece 208 removed to better show the bottom cover 226, and with a wider view to show a second quick mount/release fastener 920 that is placed on the other side of the front panel 222. As shown, the fastener 920 can be implemented as the mirror image of the fastener 900, or alternatively, the fasteners 900, 920 can be identical to each other. In addition, the quick release hinge 905 can be attached to the front panel 222 using pem studs and nuts (or other attachment mechanisms), and the pivot bracket 910 can be attached to the bottom cover 226 using pem studs and nuts (or other attachment mechanisms).

To remove the front panel 222, the quick release hinge 905 of each fastener is slid 915 laterally to disconnect the quick release hinge 905 from the pivot bracket 910. Once each quick release hinge is disconnected from its respective pivot bracket, the front panel 222 is completely disconnected from the bottom cover 226 and ready to be removed. Thus, only two sliding actions are needed to fully release the opened front panel 222 from the cabinet. This can be done for servicing of the cabinet, and then the same front panel 222 can be readily reattached to the cabinet using the quick mount/release fasteners 900, 920, or a different panel can be attached provided it includes quick release hinges that mate with the pivot brackets already attached to the bottom cover 226 of the cabinet.

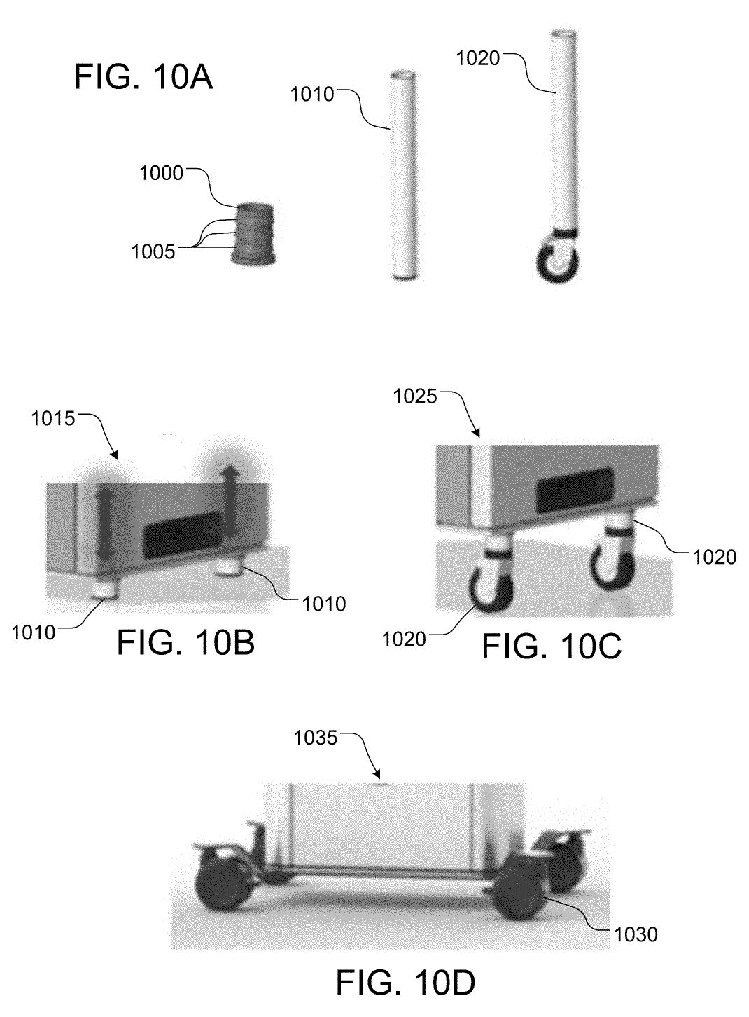

Also shown in FIG. 9B is a foot piece 1000 in place in the bottom cover 226. As will be appreciated, in accordance with some implementations, the foot piece 1000 will extend into the tube slot in the bottom piece 208 and is an example of the various structures that can be received by the cabinet in its tube slots in order to support the cabinet. FIG. 10A shows various examples of feet that can be used with the same cabinet design. These include the foot piece 1000, a foot column 1010, and a wheeled foot column 1020. The foot piece 1000 can be a molded plastic piece, and as shown, the feet for the cabinet can include mounting clips 1005 to help the cabinet retain the four feet within the tube slots (e.g., of the bottom piece 208) once they are inserted. Other attachment mechanisms for the feet can also be used.

In addition, the tube slots for the feet can extend through at least part of the frame, such as when the tube slots of the bottom piece 208 align with the tube slots in the side walls 600, 650. In this case, longer feet 1010, 1020 can be readily used. For example, FIG. 10B is a cutaway view of a cabinet 1015 with foot columns 1010 inserted therein, and FIG. 10C is a cutaway view of a cabinet 1025 with foot columns 1020 inserted therein. As will be appreciated, the lengths of the foot columns can readily be changed to change the free-standing height of the cabinet, without making any changes to the internal frame structure of the cabinets. Moreover, many different feet configurations are possible, provided they include portions that plug into the tube slots of the cabinet's frame. For example, FIG. 10D is a cutaway view of a cabinet 1035 with a wheeled trolley (with arms) 1030 that has been coupled with the tube columns of the cabinet 1035.

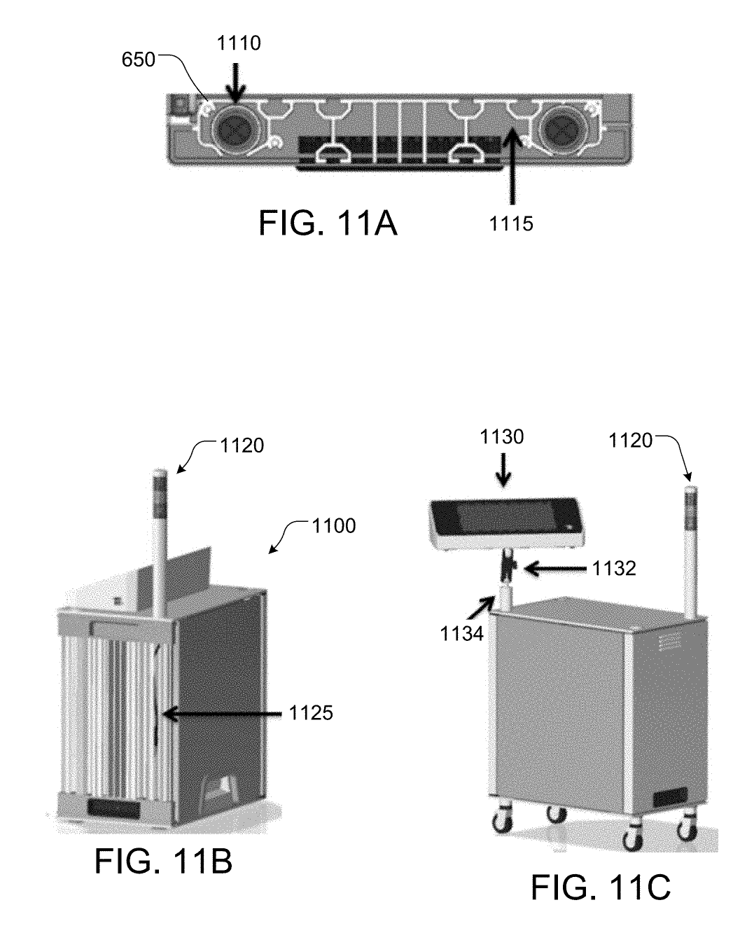

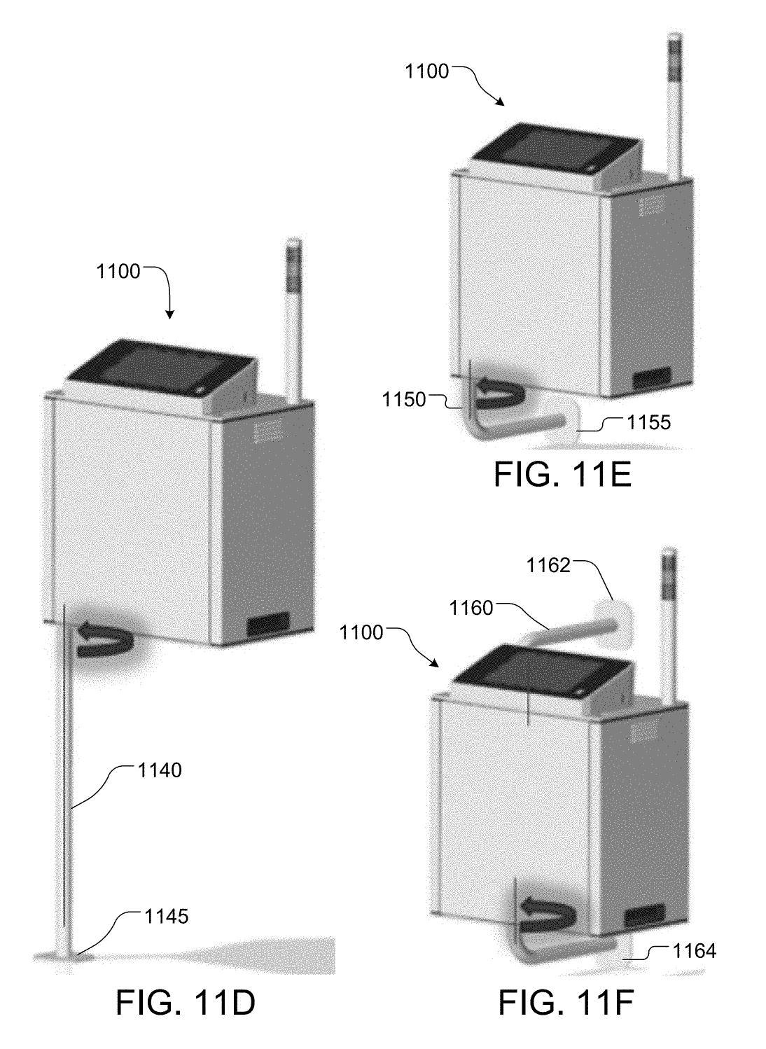

Further, the tube slots for the feet can extend all the way through the frame, such as when the tube slots of the bottom piece 208 and the side walls 600, 650 also align with the tube slots in the top piece 206. In this case, the tube slots can be used for additional attachments to the cabinet, including the attachment of electronic devices to an exterior of the cabinet. For example, FIG. 11A shows a cutaway, cross-sectional view of a cabinet's frame wall with the extruded side wall 650 therein. As shown, a tube 1110 is guided in the tube slot of the side wall 650 created by the shape of the aluminum extrusion profile. In addition, this shape can create space 1115, e.g., alongside a corresponding tube slot, to guide cable or wiring through the side wall, which can then be used for attached electronic device(s).

For example, FIG. 11B shows a cabinet 1100 with a guiding grommet 1125 in the side wall profile that receives a cable providing power and data (e.g., through a universal serial bus) to a status beacon 1120 for the cabinet 1100. As another example, FIG. 11C shows a cabinet with a display device 1130 being attached, where the power and/or data cable for the display device 1130 passes through a flexible accessory attachment joint 1132 and then through a grommet in a mounting tube 1134 (which plugs into one of the tube slots in the frame) and into the grommet in the side wall profile shape.

Moreover, the cabinet can also be mounted to other structures (or other structures can be mounted to the cabinet) using the T-slots on the exterior side(s) of the side wall(s) of the cabinet. This provides even more versatility and options for mounting the cabinet to other structures in a particular facility (e.g., a product packaging facility). Further, whether or not T-slots are used on exterior portion(s) of the side walls, when the tube slots extend part way or all the way through the frame, additional mounting options for the cabinet are possible.

FIG. 11D shows the cabinet 1100 being mounted on a pillar 1140 that is connected with the ground at a mounting point 1145. As shown, the length of the pillar 1140 puts the cabinet 1100 in a higher position, vertically displaced from the floor. Further, since the pillar 1140 is simply inserted into one of the tube slots in the cabinet 1100, using the frame structure and the weight of the cabinet 1100 to hold the cabinet in place, the cabinet 1100 is freely rotatable about the pillar 1140.

FIG. 11E shows another mounting example, where the cabinet 1100 has been mounted on a curved pillar 1150 that is connected with the wall at a mounting point 1155. As before, the cabinet 1100 is rotatable about the pillar 1150. FIG. 11F shows another mounting example, where the cabinet 1100 has been mounted on a doubly curved pillar 1160 that is connected with the wall at both first and second mounting points 1162, 1164. As before, the cabinet 1100 is rotatable about the pillar 1160. Note that mounting the cabinet in such fashions, with the cabinet 110 being easily rotatable, can improve accessibility and usability of the cabinet 1100.

While this specification contains many implementation details, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination. Thus, unless explicitly stated otherwise, or unless the knowledge of one of ordinary skill in the art clearly indicates otherwise, any of the features of the embodiment described above can be combined with any of the other features of the embodiment described above.

Thus, particular embodiments of the invention have been described. Other embodiments are within the scope of the following claims.

What is claimed is:

1. A cabinet comprising:
a frame configured to receive equipment within an interior portion of the frame, wherein the frame defines at least part of a channel on an exterior portion of the frame;
at least one side panel that attaches to the frame; and
a handle located in the at least one side panel, wherein the handle defines a vent hole within the handle, and the vent hole is aligned with the channel, thereby allowing air to flow through the vent hole into the channel to cool the equipment when present within the interior portion of the frame.

2. The cabinet of claim 1, wherein the handle is a recessed handle that extends through the at least one side panel, and the at least one vent hole is located in an upper, interior portion of the recessed handle.

3. The cabinet of claim 2, wherein the recessed handle attaches to the frame and includes a retaining edge that holds the at least one side panel to the frame, thereby forming the channel between the exterior portion of the frame and an interior portion of the at least one side panel.

4. The cabinet of claim 3, wherein the recessed handle comprises an injection molded part including a molded quick release clip to hold the recessed handle to the at least one side panel.

5. The cabinet of claim 3, comprising screws or bolts that attach the recessed handle to the frame, and pins that attach the at least one side panel to the frame by mating with keyhole slots in the frame.

6. The cabinet of any of claims 1-5, 9, and 10, comprising:
a front panel;
quick release hinges configured and arranged to attach the front panel to the cabinet, such that the front panel is fully removable from an open position using the quick release hinges when the front panel is in the open position; and
a gasket configured and arranged to form a seal between front panel and the frame, when the front panel is in a closed position, to prevent ingress of contaminants into the interior portion of the frame when the front panel is in the closed position.

7. The cabinet of claim 6, wherein the gasket includes a pitched portion to direct a flow of liquid responsive to gravity.

8. The cabinet of claim 6, wherein the frame comprises one or more exterior edges, adjacent to the gasket, that are angled with respect to a plane associated with the gasket, such that liquid is directed away from the gasket by the one or more angled exterior edges, responsive to gravity, when the cabinet is positioned with the plane perpendicular to the direction of the gravity.

9. The cabinet of claim 2, comprising an air filter located in a top portion of the cabinet and separating the channel on the exterior portion of the frame from the interior portion of the frame, wherein the recessed handle is located in a bottom portion of the cabinet, the frame comprises a material that defines a portion of the channel between the recessed handle and the air filter, and the material comprises a heat sink.

10. The cabinet of claim 9, comprising a modular fan assembly located in the bottom portion of the cabinet.

11. A cabinet comprising:
a frame comprising two walls on opposite sides of the frame; and
at least one panel configured to attach to at least one side of the frame separate from the two walls;
wherein each of the two walls on the opposite sides of the frame defines a shape that (i) receives a structure to support the cabinet, and (ii) receives fasteners on both sides of the wall to mount equipment on both an interior portion of the frame and an exterior portion of the frame.

12. The cabinet of claim 11, wherein the shape that receives the fasteners on both sides of the wall comprise multiple T-slots.

13. The cabinet of claim 12, wherein the multiple T-slots comprise:
at least five T-slots on the wall side interior to the frame; and
at least two T-slots on the wall side exterior to the frame.

14. The cabinet of claim 13, wherein a distance between the at least two T-slots is equivalent to a distance between the first and third of the at least five T-slots, which is equivalent to a distance between the second and fourth of the at least five T-slots, which is equivalent to a distance between the third and fifth of the at least five T-slots.

15. The cabinet of any of claims 11-14, wherein each of the two walls comprises extruded aluminum that forms the shape.

16. The cabinet of claim 15, wherein the frame comprises the two extruded aluminum walls, a molded plastic top piece, and a molded plastic bottom piece, and the cabinet comprises cage nut assemblies that couple the two extruded aluminum walls with the top and bottom molded plastic pieces.

17. The cabinet of claim 16, wherein the two extruded aluminum walls and the top and bottom molded plastic pieces define tube slots configured and arranged to interchangeably receive feet structures or pillar structures.

18. The cabinet of claim 16, wherein a proper subset of the cage nut assemblies have associated connectors through which side panels are attached to the cabinet.

19. The cabinet of claim 15, wherein the shape that receives the structure to support the cabinet defines holes on either end of the wall configured to interchangeably receive feet structures or pillar structures.

20. The cabinet of claim 19, wherein the shape includes a profile that receives a cable and grommet.

21. A cabinet comprising features recited in any two or more of claims 1-20.
